(19) United States
(12) Patent Application Publication
(10) Pub. No.: US 2025/0203946 A1
(43) Pub. Date: Jun. 19, 2025

(54) SEMICONDUCTOR DEVICE WITH STACKED DEVICE TYPES

(71) Applicant: INTERNATIONAL BUSINESS MACHINES CORPORATION, ARMONK, NY (US)

(72) Inventors: Shay Reboh, Albany, NY (US); Jay William Strane, Wappingers Falls, NY (US); Junli Wang, Slingerlands, NY (US); Chen Zhang, Santa Clara, CA (US); Brent A. Anderson, Jericho, VT (US)

(21) Appl. No.: 18/545,188

(22) Filed: Dec. 19, 2023

(51) Int. Cl. H01L 29/786; H01L 21/8238; H01L 27/092; H01L 29/06; H01L 29/423; H01L 29/66; H01L 29/775

(52) U.S. Cl. CPC H10D 30/6757; H10D 30/014; H10D 30/43; H10D 30/6735; H10D 62/121; H10D 64/017; H10D 84/0167; H10D 84/0172; H10D 84/038; H10D 84/85

(57) ABSTRACT

A semiconductor device is provided. The semiconductor device includes a first stacked nanosheet structure and a second stacked nanosheet structure each including a first nanosheet structure formed at a first level and a second nanosheet structure formed at a second level. A configuration of the first stacked nanosheet structure on the first level is different than a configuration of the second stacked nanosheet structure on the first level, or the configuration of the first stacked nanosheet structure on the second level is different than a configuration of the second stacked nanosheet structure on the second level.

### FIELD OF THE INVENTION

The present disclosure relates to fabrication methods and resulting structures for semiconductor devices. More specifically, the present disclosure relates to fabrication methods and resulting structures for field effect transistors (FETs) with stacked n-type and p-type nanosheets for complementary metal oxide semiconductor (CMOS) technologies.

### BACKGROUND

In certain semiconductor device fabrication processes, a large number of semiconductor devices, such as n-type field effect transistors (nFETs) and p-type field effect transistors (pFETs), may be fabricated on a single wafer. Non-planar transistor device architectures (e.g., fin-type FETs (FinFETs) and nanosheet FETs) can provide increased device density and increased performance over planar transistors. To further increase the transistor density, one approach is to stack one device over another to double the active density at a given footprint. The stacked FET can have various different forms, e.g., one nanosheet (NS) device over another nanosheet device, one FINFET device over another FINFET device, one FINFET device over one nanosheet device, one nanosheet device over one FINFET device, one planar device over one FINFET device, one planar device over another nanosheet device, etc.

### SUMMARY

Embodiments of the present disclosure relate to a semiconductor device. The semiconductor device includes a first stacked nanosheet structure and a second stacked nanosheet structure each including a first nanosheet structure formed at a first level and a second nanosheet structure formed at a second level. A configuration of the first stacked nanosheet structure on the first level is different than a configuration of the second stacked nanosheet structure on the first level, or the configuration of the first stacked nanosheet structure on the second level is different than a configuration of the second stacked nanosheet structure on the second level.

Embodiments of the present disclosure relate to an electronic device that includes a semiconductor device. The semiconductor device includes a first stacked nanosheet structure and a second stacked nanosheet structure each including a first nanosheet structure formed at a first level and a second nanosheet structure formed at a second level. A configuration of the first stacked nanosheet structure on the first level is different than a configuration of the second stacked nanosheet structure on the first level, or the configuration of the first stacked nanosheet structure on the second level is different than a configuration of the second stacked nanosheet structure on the second level.

Embodiments of the present disclosure relate to a semiconductor device. The semiconductor device includes a first stacked nanosheet structure and a second stacked nanosheet structure each including a first nanosheet structure formed at a first level and a second nanosheet structure formed at a second level, the first and second stacked nanosheet structures including at least one epitaxial layer (or source/drain terminal). A configuration of the at least one epitaxial layer of the first stacked nanosheet structure at the first level is different from a configuration of the at least one epitaxial layer of the second stacked nanosheet structure at the first level, or the configuration of the at least one epitaxial layer of the first stacked nanosheet structure at the second level is different from a configuration of the at least one epitaxial layer of the second stacked nanosheet structure at the second level.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1 is a cross-sectional view of a semiconductor device at an intermediate stage of the fabrication process, according to embodiments.

FIG. 2 is an expanded cross-sectional view of the semiconductor device of FIG. 1, according to embodiments.

FIG. 3 is a cross-sectional view of the semiconductor device of FIG. 2 after additional fabrication operations, according to embodiments.

FIG. 4 is a cross-sectional view of the semiconductor device of FIG. 3 after additional fabrication operations, according to embodiments.

FIG. 5 is a cross-sectional view of the semiconductor device of FIG. 4 after additional fabrication operations, according to embodiments.

FIG. 6 is a cross-sectional view of the semiconductor device of FIG. 5 after additional fabrication operations, according to embodiments.

FIG. 7 is a cross-sectional view of the semiconductor device of FIG. 6 after additional fabrication operations, according to embodiments.

FIG. 8 is a cross-sectional view of the semiconductor device of FIG. 7 after additional fabrication operations, according to embodiments.

FIG. 9 is a cross-sectional view of the semiconductor device of FIG. 8 after additional fabrication operations, according to embodiments.

FIG. 10 is a cross-sectional view of the semiconductor device of FIG. 9 after additional fabrication operations, according to embodiments.

FIG. 11 is a cross-sectional view of the semiconductor device of FIG. 10 after additional fabrication operations, according to embodiments.

FIG. 12 is a cross-sectional view of the semiconductor device of FIG. 11 after additional fabrication operations, according to embodiments.

FIG. 13 is a cross-sectional view of the semiconductor device of FIG. 12 after additional fabrication operations, according to embodiments.

FIG. 14 is a cross-sectional view of the semiconductor device of FIG. 13 after additional fabrication operations, according to embodiments.

FIG. 15 is a cross-sectional view of the semiconductor device of FIG. 14 after additional fabrication operations, according to embodiments.

FIG. 16 is a cross-sectional view of the semiconductor device of FIG. 15 after additional fabrication operations, according to embodiments.

FIG. 17 is a cross-sectional view of the semiconductor device of FIG. 16 after additional fabrication operations, according to embodiments.

FIG. 18 is a cross-sectional view of the semiconductor device of FIG. 17 after additional fabrication operations, according to embodiments.

FIG. 19 is a cross-sectional view of a semiconductor device including a single PFET standard drive current device, and a single NFET standard drive current device, at an intermediate stage of the fabrication process, according to embodiments.

FIG. 20 is a cross-sectional view of a semiconductor device including a stacked CMOS device, a stacked PFET high drive current device, and a stacked NFET high drive current device, at an intermediate stage of the fabrication process, according to embodiments.

FIG. 21 is a cross-sectional view of a semiconductor device at an intermediate stage of the fabrication process where the semiconductor device includes merged epitaxial layers, according to embodiments.

### DETAILED DESCRIPTION

The present disclosure describes stacked FET devices and methods of manufacturing the stacked FET devices. In particular, the present disclosure describes stacked complementary metal oxide semiconductor (CMOS) devices having a plurality of stacked structures having different compositions and device types. In particular, at least a first one of the stacked structures includes a first device type (e.g., stacked CMOS, stacked pFET, stacked nFET, single pFET, single nFET) and at least a second one of the stacked structures includes a second device type. In certain examples, the present embodiments co-integrate P/P type and/or N/N type with P/N type and/or N/P type epitaxial regions. In some of these examples, the P/P type and N/N type have merged sources and/or drains.

The flowcharts and cross-sectional diagrams in the Figures illustrate methods of manufacturing stacked FET devices according to various embodiments. In some alternative implementations, the manufacturing steps may occur in a different order than that which is noted in the Figures, and certain additional manufacturing steps may be implemented between the steps noted in the Figures. Moreover, any of the layered structures depicted in the Figures may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of an FET is related to the electrical conductivity of the channel material. If the channel material has a relatively high conductivity, the FET can be made with a correspondingly smaller wafer footprint. A known method of increasing channel conductivity and decreasing FET size is to form the channel as a nanostructure. For example, a so-called gate-all-around (GAA) nanosheet FET is a known architecture for providing a relatively small FET footprint by forming the channel region as a series of nanosheets. In a known GAA structure, a nanosheet-based FET includes a source region, a drain region and stacked nanosheet channels between the source and drain regions. Semiconductor nanosheet FET devices typically include one or more suspended nanosheets that serve as the channel. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized. For n-type FETs, the channel nanosheets are typically silicon (Si) and the sacrificial nanosheets are typically silicon germanium (SiGe). For p-type FETs, the channel nanosheets can be SiGe and the sacrificial nanosheets can be Si. In some implementations, the channel nanosheet of a p-type FET can be SiGe or Si, and the sacrificial nanosheets can be Si or SiGe. Forming the GAA nanosheets from alternating layers of channel nanosheets formed from a first type of semiconductor material (e.g., Si for n-type FETs, and SiGe for p-type FETs) and sacrificial nanosheets formed from a second type of semiconductor material (e.g., SiGe for n-type FETs, and Si for p-type FETs) provides improved channel electrostatics control, which may be helpful for continuously scaling gate lengths down to seven (7) nanometer CMOS technology and below.

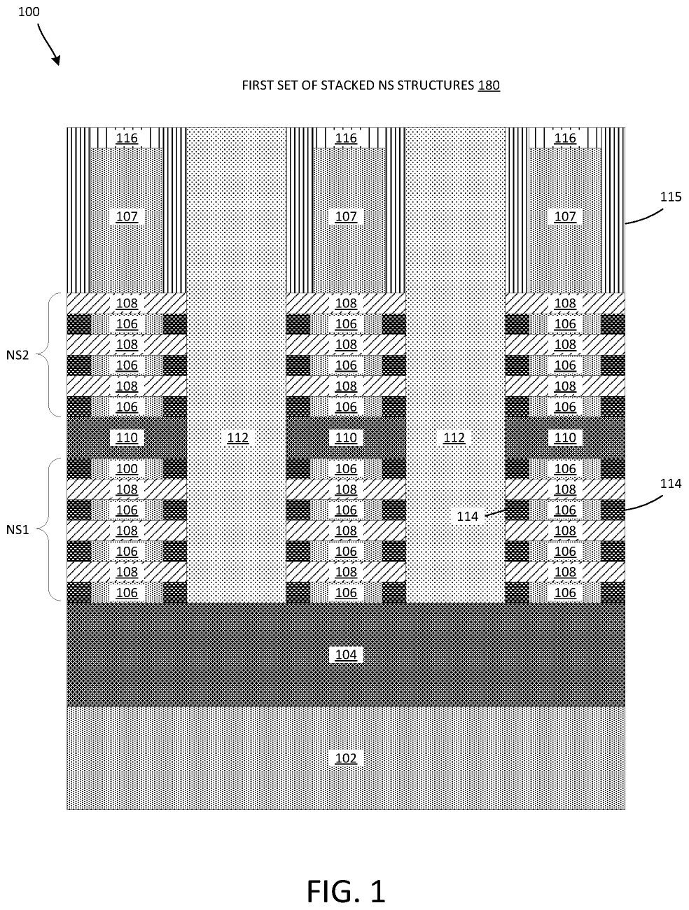

Referring now to the drawings in which like numerals represent the same or similar elements and initially to FIG. 1, this figure depicts a cross-sectional view of a semiconductor device 100 including a first set of stacked nanosheet structures 180 at an intermediate stage of the manufacturing process, according to embodiments. In particular, FIG. 1 illustrates the process at a stage after forming the bottom dielectric isolation layer, the stacked nanosheet structures, the middle dielectric isolation layer, the dummy gates, the gate spacers, and the inner spacers for the stacked FET. As shown in FIG. 1, a substrate 102 is provided. The substrate 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 102 may also be a semiconductor on insulator (SOI) substrate. The substrate 102 may be comprised of any other suitable material(s) than those listed above.

As shown in FIGS. 1, a bottom dielectric isolation (BDI) layer 104 is formed on the substrate 102. The bottom dielectric isolation layer 104 may comprise one or more insulating materials such as a low-k material, silicon nitride (SiN), silicon boron carbonitride (SiBCN), silicon oxycarbonitride (SiOCN), silicon oxynitride (SiON), silicon carbide (SiC), and/or the like. However, it should be appreciated that the BDI layer 104 may include other suitable materials. Moreover, in some embodiments, the BDI layer 104 may be omitted.

In some embodiments, shallow trench isolation (STI) regions (not shown) may be formed into the semiconductor substrate 102. In general, shallow trench isolation is an integrated circuit feature which prevents electric current leakage between adjacent semiconductor device components. STI is generally used on CMOS process technology nodes of 250 nanometers and smaller. STI regions are created early during the semiconductor device fabrication process before transistors are formed. The STI process involves etching a pattern of trenches in the silicon, depositing one or more dielectric materials (such as silicon dioxide) to fill the trenches, and removing the excess dielectric using a technique such as chemical-mechanical planarization.

Referring again to FIG. 1, the first set of stacked nanosheet structures 180 of the semiconductor device 100 includes a bottom nanosheet structure NS1 (or first nanosheet structure), and a top nanosheet structure NS2 (or second nanosheet structure), that are separated by a middle dielectric isolation (MDI) layer 110. The bottom nanosheet structure NS1 includes alternating layers of a sacrificial layer 106 and a semiconductor layer 108. In the embodiment shown in FIG. 1, the top nanosheet structure NS2 similarly includes alternating layers of a sacrificial layer 106 and a semiconductor layer 108.

Although the structure shown in FIG. 1 is shown at a stage in the manufacturing process after the bottom nanosheet structure NS1 and the top nanosheet structure NS2 have already been formed (for the sake of simplicity), one example process of forming these nanosheet stack structures is described below. In this example, a bottom nanosheet stack NS1 is formed on the substrate 102. The bottom nanosheet stack NS1 initially includes a sacrificial layer 106 that is formed on the BDI layer 104, followed by the formation of a semiconductor layer 108. In an example, the sacrificial layer 106 is composed of silicon-germanium (e.g., SiGe35, or more generally, where the Ge ranges from about 15-35%). Further, the first (or bottommost) semiconductor layer 108 is formed on an upper surface of the first one of the sacrificial layers 106. In an example, the semiconductor layer 108 is composed of silicon. Several additional layers of the sacrificial layer 106 and the semiconductor layer 108 are alternately formed. It should be appreciated that any suitable number of alternating layers of sacrificial layers 106 and semiconductor layers 108 may be formed. Although not shown in the figures, a temporary layer (such as SiGe with Ge % 50˜70%, which will be converted to the middle dielectric isolation (MDI) layer 110 later) is formed on the bottom nanosheet structure NS1. In a process similar to that described above, a top nanosheet structure NS2 is formed. It should be appreciated that the total number of alternating layers in the top nanosheet structure NS2 may be any suitable number.

In certain embodiments, the sacrificial layers 106 have a vertical thickness ranging, for example, from approximately 3 nm to approximately 20 nm. In certain embodiments, the semiconductor layers 108 have a vertical thickness ranging, for example, from approximately 3 nanometers (nm) to approximately 10 nm. Although the range of 3-20 nm is cited as an example range of thickness, other thicknesses of these layers may be used. In certain examples, certain of the sacrificial layers 106 and/or the semiconductor layers 108 may have different thicknesses relative to one another. Therefore, multiple epitaxial growth processes can be performed to form the sacrificial layers 106 and the semiconductor layers 108.

In certain embodiments, it may be desirable to have a small vertical spacing (VSP) between adjacent nanosheet layers in a stack of nanosheets to reduce the parasitic capacitance and to improve circuit speed. For example, the VSP (the distance between the bottom surface of a first nanosheet layer and the top surface of an adjacent second nanosheet layer) may range from 5 nm to 15 nm. However, the VSP must be of a sufficient value to accommodate the gate stack that will be formed in the spaces created by later removal of the sacrificial layers.

In certain examples, a dummy gate 107 (or dummy polycrystalline (PC) layer) is formed on the top nanosheet structures NS2. The dummy gate 107 may be formed by any suitable deposition technique known to one of skill in the art. In one example, the dummy gate 107 is formed by depositing a thin SiO₂ dummy gate oxide layer (not shown), followed by depositing a layer of amorphous silicon (a-Si) as the dummy gate 107. The dummy gate 107 may be composed of polycrystalline silicon (poly silicon), amorphous silicon, and/or an oxide, such as, SiO₂. Gate patterning may be performed by first patterning a gate hardmask 116 and then using the patterned gate hardmask 116 to etch the dummy gates 107. After the dummy gate 107 is formed and a spacer material is conformally deposited, the gate spacer 115 is formed. After that, the sacrificial layers 106 of the stacked nanosheets NS1 and NS2 at the source/drain regions which are not protected by gate hardmask 116 and gate spacers 115 are recessed in a horizontal direction, followed by inner spacer 114 formation (only two labeled in FIG. 1 for clarity). A selective etching process using, for example, a boron-based chemistry or a chlorine-based chemistry may be used, which selectively recesses the exposed portions of the sacrificial layers 106 without significantly attacking the surrounding materials. Then, the inner spacers 114 are formed in the indents created by the removal of the portions of the sacrificial layers 106. An isotropic etching process may be performed to clean up the edges of the inner spacers 114 and the semiconductor layers 108.

Also, in certain embodiments, although not shown in FIG. 1, the hard mask 116 may be removed after the formation of the bottom nanosheet structure NS1 and the top nanosheet structure NS2. As shown in FIG. 1, a dielectric gap fill layer 112 is formed between the different nanosheet stack structures. The gap fill layer 112 may be any suitable dielectric material such as an oxide-based dielectric, such as a flowable chemical vapor deposition (FCVD) oxide.

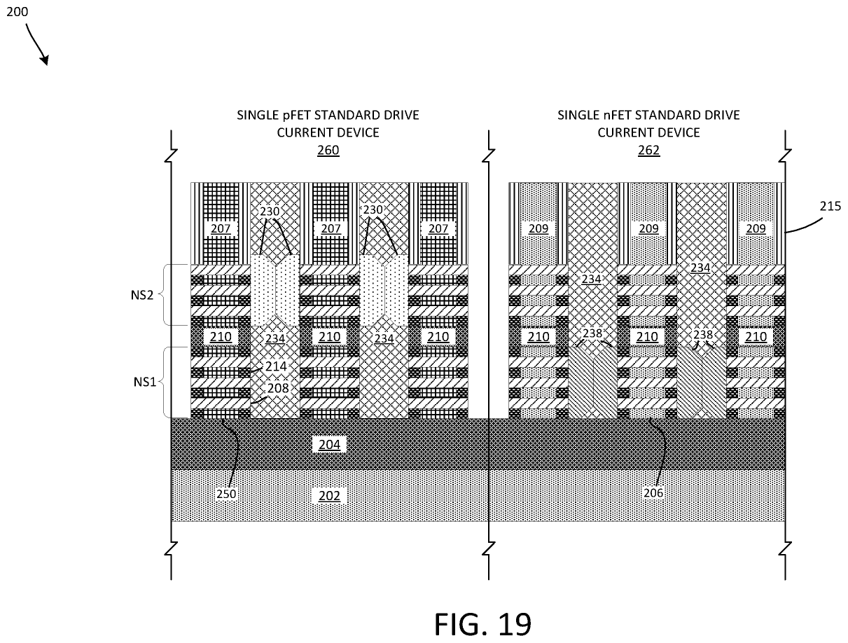

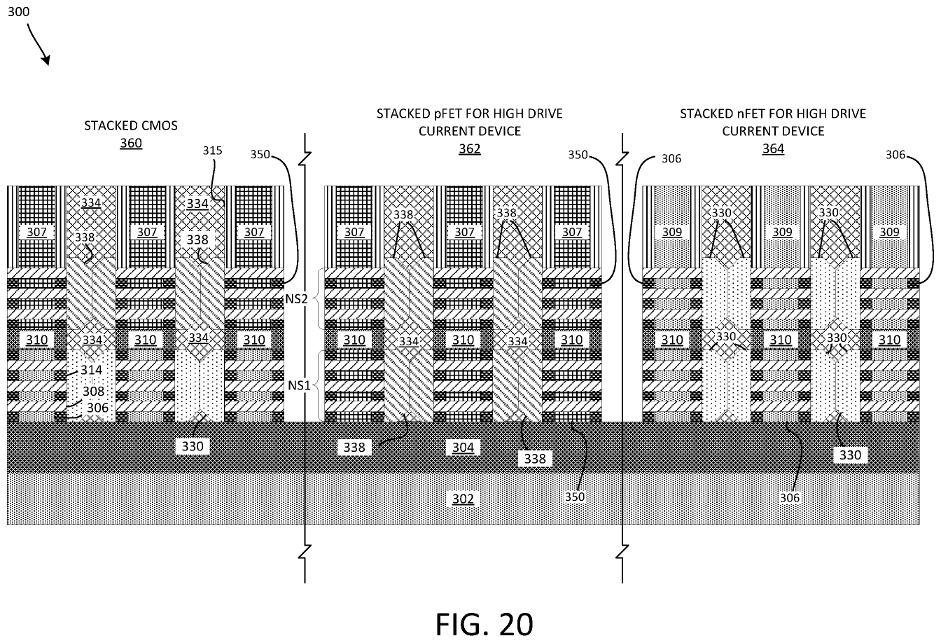

As used herein, the term “stacked nanosheet structure” refers to a stack of a “bottom nanosheet structure” (or first nanosheet structure) and a “top nanosheet structure” (or second nanosheet structure) that is formed on the bottom nanosheet structure. The term “nanosheet structure” may refer to the nanosheet structure associated with either the top or the bottom levels (also referred to as first and second levels) of the stacked nanosheet structure. The nanosheet structure includes the alternating layers of semiconductor layer and WFM layers (or a nanosheet stack), and also includes either a dielectric layer or an epitaxial layer that is in contact with the nanosheet stack. For example, in the embodiment shown in FIG. 19, the bottom nanosheet structure NS1 of the single pFET standard drive current device 260 includes the alternating layers of semiconductor layers and WFM layers (or nanosheet stack) as well as the gap fill layer 234 in contact with the nanosheet stack. As also shown in FIG. 19, the top nanosheet structure NS2 of the single pFET standard drive current device 260 includes the alternating layers of semiconductor layers and WFM layers (or nanosheet stack) as well as the epitaxial layer 230 in contact with the nanosheet stack. Because the bottom nanosheet structure NS1 of the single pFET standard drive current device 260 does not include the epitaxial layer it may be thought of as a dummy FET because it does not include a terminal that allows the structure to function as a FET. In contrast, the embodiment shown in FIG. 20 does not include any dummy FETs because both the top and the bottom nanosheet structures include the epitaxial layer. In other words, the term “nanosheet structure” as used herein allows for both the presence or absence of the associated epitaxial layer (i.e., a FET or a dummy FET).

As used in the embodiments described herein, the term “configuration” of the respective nanosheet structures may refer to at least one of the following: the presence or absence of an epitaxial layer adjacent to the nanosheet stack; the doping type (i.e., p-type or n-type) of the epitaxial layer; and the type (i.e., p-type or n-type) of the WFM layer of the nanosheet stack. Thus, a difference in a configuration between a first nanosheet structure and a second nanosheet structure means that there is at least one difference as described above between the first and second nanosheet structure.

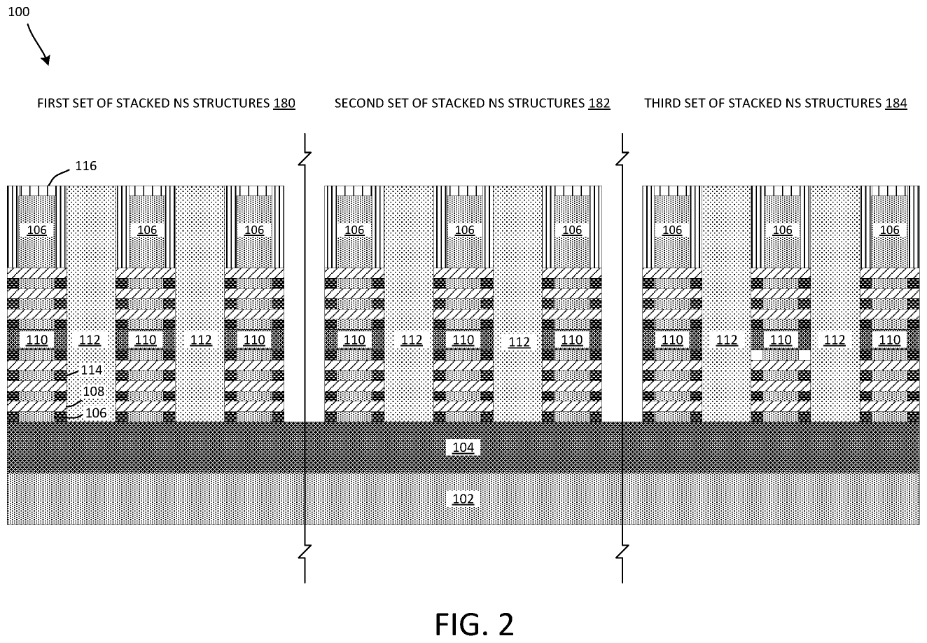

Referring now to FIG. 2, this figure is a cross-sectional view of the semiconductor device 100 of FIG. 1 with an expanded view of nine different stacked nanosheet structures, according to embodiments. Although only three stacked nanosheet structures were shown in FIG. 1 (i.e., for the sake of clarity with regard to labelling all elements of the semiconductor device 100), FIG. 2 shows three sets of stacked nanosheet structures (i.e., first set of stacked nanosheet structures 180, the second set of stacked nanosheet structures 182 and the third set of stacked nanosheet structure 184) each including three stacks (i.e., nine total stacks), where each set of three stacked nanosheet structures is separated by a break line in FIG. 2. It should be appreciated that the first set of stacked nanosheet structures 180 in FIG. 1 is structurally the same as any of the three sets of nanosheet stacks shown in FIG. 2 at this stage of the manufacturing process. Moreover, it should be appreciated that the total number of stacked nanosheet structures is not limited to any particular number, and the embodiments related to FIGS. 1-18 show a number of different sets of nanosheet stacks that is suitable to illustrate the concepts of the present disclosure. For example, FIG. 2 is at the same stage of the manufacturing process as FIG. 1. However, FIG. 2 shows an expanded view of FIG. 1 without all of the reference numerals for the sake of clarity and ease of understanding.

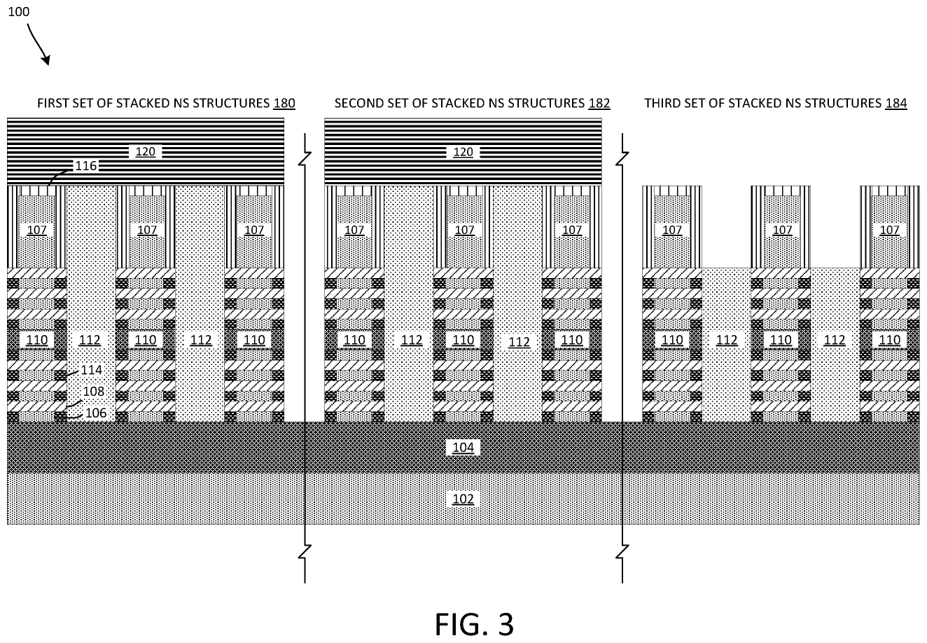

Referring now to FIG. 3, this figure is a cross-sectional view of the semiconductor device of FIGS. 1 and 2 after additional fabrication operations, according to embodiments. As shown in FIG. 3, a mask 120 is formed on the first set of stacked nanosheet structures 180 and on the second set of stacked nanosheet structures 182 according to standard lithographic procedures. After the mask 120 is formed, a suitable material removal process, such as reactive ion etching (RIE), wet etching, or chemical oxide removal (COR), is used to remove a portion of the gap fill layer 112 in the region corresponding to the third set of stacked nanosheet structures 184. In this example, the gap fill layer 112 in the region corresponding to the third set of stacked nanosheet structures 184 is removed down to a lower level. It should be appreciated that the material removal step creates a vertical offset that corresponds approximately to the height of the bottom FET such that when the gap fill material layer 112 is recessed, the top nanosheet structure NS2 for the third set of nanosheet structures 184 is exposed.

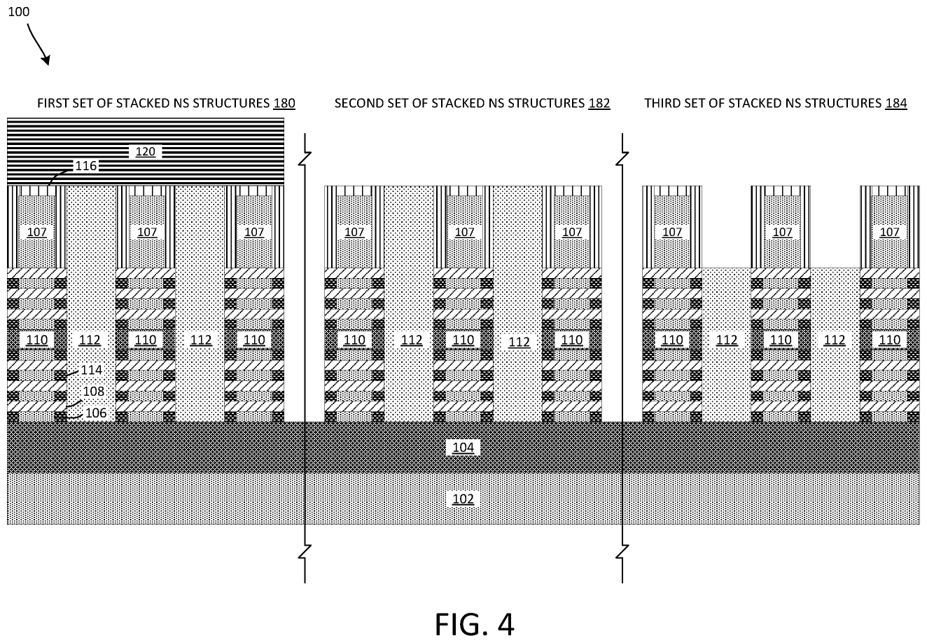

Referring now to FIG. 4, this figure is a cross-sectional view of the semiconductor device of FIG. 3 after additional fabrication operations, according to embodiments. As shown in FIG. 4, the mask 120 is removed and a new mask 120 is provided by standard lithography processes in an area over the first set of stacked nanosheet structures 180. Thus, at this stage, the hardmask 116 and the gap fill layer 112 in the area corresponding to the second set of stacked nanosheet structures 182 are exposed for further processing.

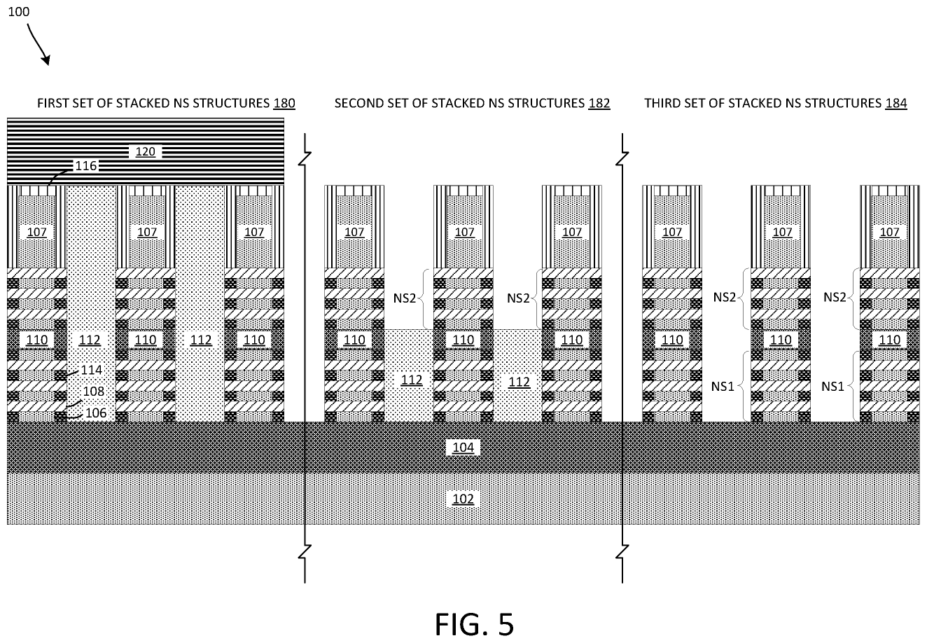

Referring now to FIG. 5, this figure is a cross-sectional view of the semiconductor device 100 of FIG. 4 after additional fabrication operations, according to embodiments. As shown in FIG. 5, a suitable material removal process, such as reactive ion etching (RIE), is used to remove further portions of the gap fill layer 112 in the region corresponding to the third set of stacked nanosheet structures 184 and the region corresponding to the second set of stacked nanosheet structures 182. In this example, the gap fill layer 112 in the region corresponding to the second set of stacked nanosheet structures 182 is removed down to a level that generally corresponds to the top of the MDI layer 110 (or more generally this could be at any place above the level of the top of the bottom nanosheet structures NS1). Thus, the sidewalls of the semiconductor layers 108 and the inner spacers 114 are exposed for the top nanosheet structures NS2 in the second set of stacked nanosheet structures 182. Also, the gap fill layer 112 in the region corresponding to the third set of stacked nanosheet structures 184 is completely removed. Thus, the sidewalls of the semiconductor layers 108 and the inner spacers 114 are exposed for both the bottom nanosheet structures NS1 and the top nanosheet structures NS2 for the third set of stacked nanosheet structures 184.

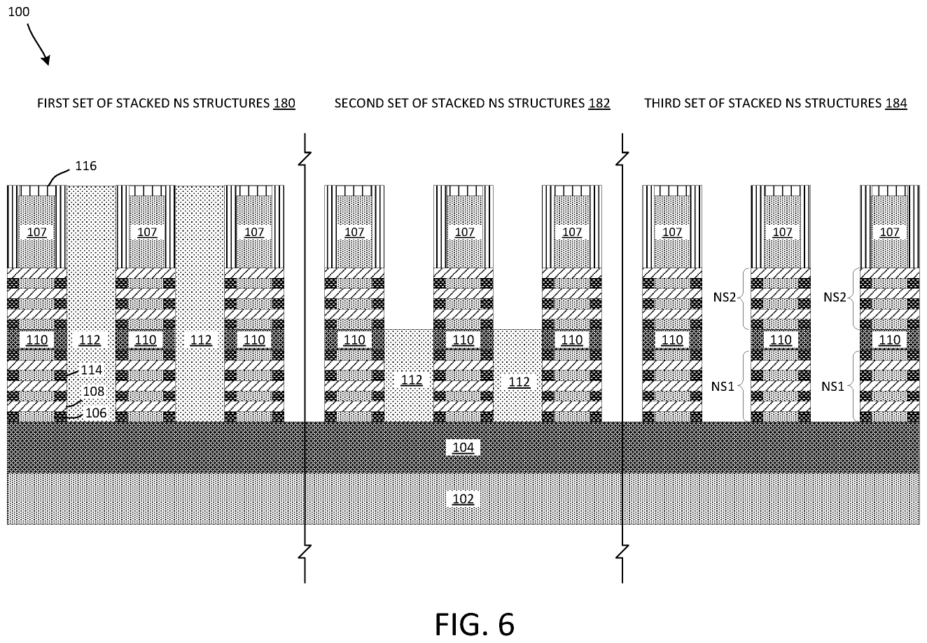

Referring now to FIG. 6, this figure is a cross-sectional view of the semiconductor device of FIG. 5 after additional fabrication operations, according to embodiments. As shown in FIG. 6, the mask 120 is removed in an area over the first set of stacked nanosheet structures 180. Thus, at this stage, the hardmask 116 and the gap fill layer 112 in the area corresponding to the first set of stacked nanosheet structures 180 are exposed for further processing.

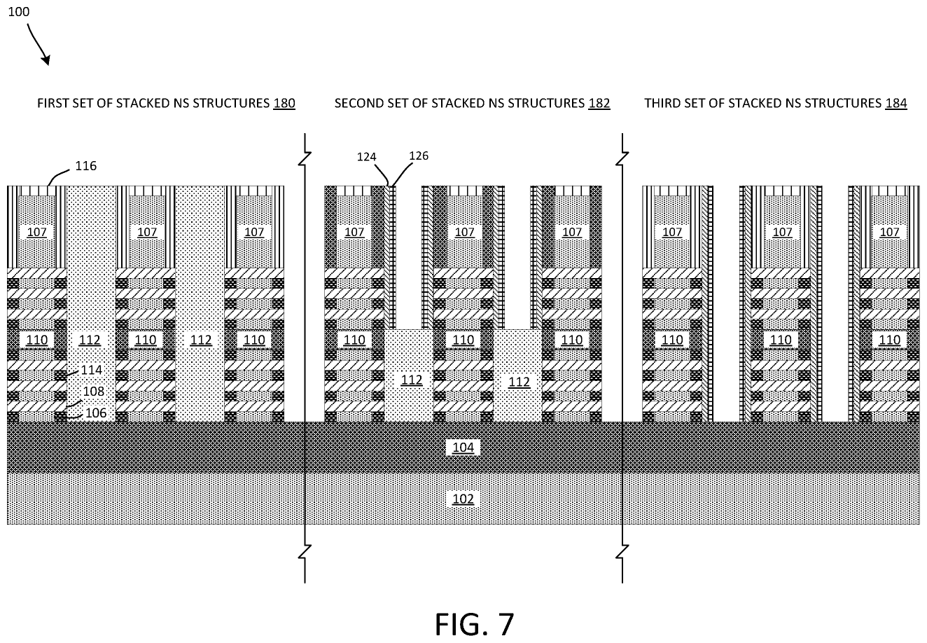

Referring now to FIG. 7, this figure is a cross-sectional view of the semiconductor device 100 of FIG. 6 after additional fabrication operations, according to embodiments. As shown in FIG. 7, sidewall spacers are formed to cover the sidewalls of the semiconductor layers 108 and the inner spacers 114 for the top nanosheet structures NS2 in the second set of stacked nanosheet structures 182. The sidewall spacers include an oxide layer 124 and a nitride layer 126. In one example, the oxide layer 124 is first conformally deposited across all the surfaces of the semiconductor device 100, and then a suitable etching process is used to remove the horizontal portions thereof, leaving the vertical portions of the oxide layer 124 to cover the sidewalls. Then, the nitride layer 126 is formed over the oxide layer 124 in a similar manner to how the oxide layer 124 was formed. In another example, the oxide layer 124 and the nitride layer 126 are both formed before the etching process is performed. Thus, the oxide layer 124 and the nitride layer 126 are formed to cover the sidewalls of the semiconductor layers 108 and the inner spacers 114 for both the bottom nanosheet structures NS1 and the top nanosheet structures NS2 for the third set of stacked nanosheet structures 184. The oxide layers 124 and the nitride layers 126 allow for subsequent formation of the epitaxial layers only on the portions of the nanosheet stacks that are not covered by the oxide layers 124 and the nitride layers 126. In other words, the oxide layers 124 and nitride layers 126 function as a blocking layer to temporarily prevent epitaxial growth on these surfaces.

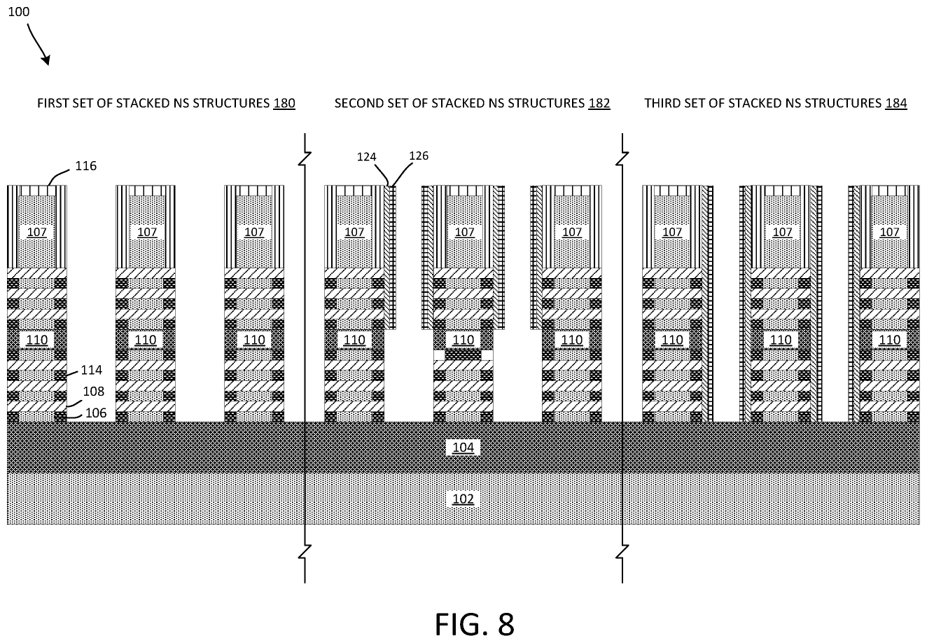

Referring now to FIG. 8, this figure is a cross-sectional view of the semiconductor device 100 of FIG. 7 after additional fabrication operations, according to embodiments. As shown in FIG. 8, the remaining portions of the gap fill layer 112 are removed all the way down to the BDI layer 104. Thus, at this stage, the semiconductor layers 108 and the inner spacers 114 are exposed for the top nanosheet structures NS2 and the bottom nanosheet structures NS1 in the first set of stacked nanosheet structures 180, and for only the bottom nanosheet structures NS1 in the second set of stacked nanosheet structures 182. For the third set of stacked nanosheet structures 184, both the bottom nanosheet structures NS1 and the top nanosheet structures NS2 are still covered by the sidewall spacer (i.e., in this example the sidewall spacer includes the oxide layers 124 and nitride layers 126). If the nanosheet stacks are exposed, it will allow for the subsequent growth of the epitaxial layers, as discussed below.

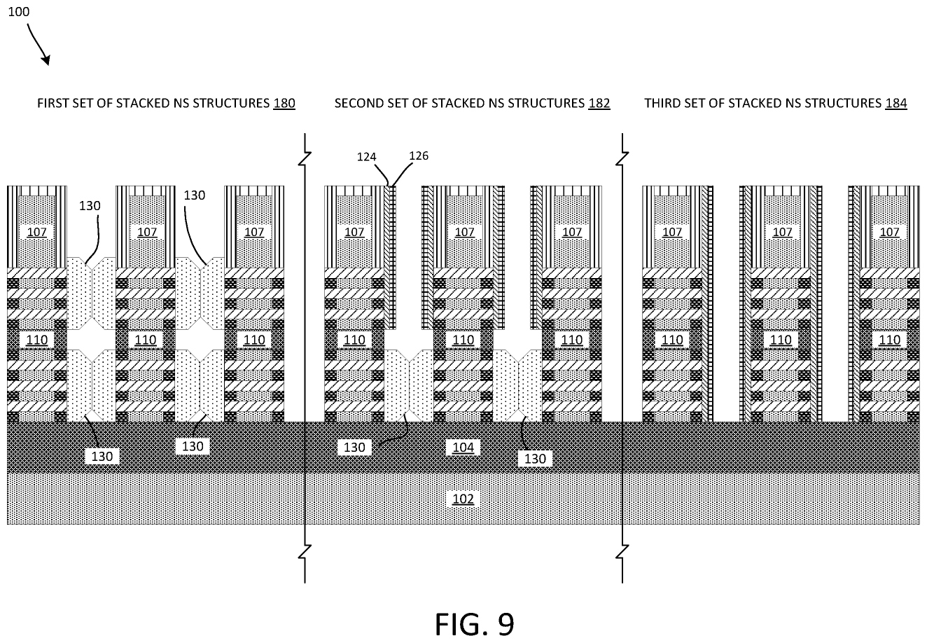

Referring now to FIG. 9, this figure is a cross-sectional view of the semiconductor device 100 of FIG. 8 after additional fabrication operations, according to embodiments. As shown in FIG. 9, first type epitaxial layers 130 are formed on the exposed top nanosheet structures NS2 and the bottom nanosheet structures NS1 in the first set of stacked nanosheet structures 180 and are formed only on the bottom nanosheet structures NS1 in the second set of stacked nanosheet structures 182. That is, because the remaining nanosheet stacks are still covered by the oxide layer 124 and the nitride layer 126, the growth of the first type epitaxial layer 130 does not take place in these regions. In one example, the first type epitaxial layers 130 include a silicon-based material. In certain embodiments, the first type epitaxial layer 130 includes a p-type dopant. However, in other embodiments, the first type epitaxial layer 130 includes an n-type dopant. Thus, in this example, the first set of stacked nanosheet structures 180 include a combination of epitaxial layers that have the same doping type (either a p-type or n-type) for the first type epitaxial layers 130 for both the top nanosheet structures NS2 and the bottom nanosheet structures NS1. This combination of having the same doping types for both the first type epitaxial layers 130 on the top and bottom nanosheet structures NS1 and NS2 enable a first type of device (e.g., a stacked pFET or stacked nFET device for a high drive current device depending on the doping type).

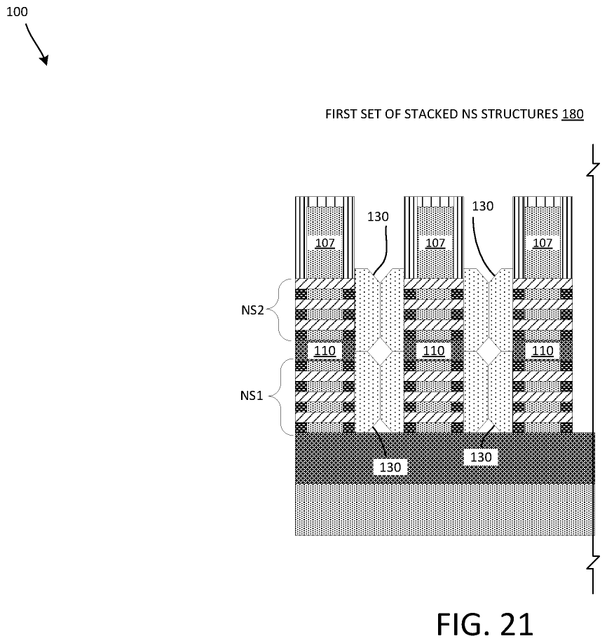

In FIG. 9, for the first set of stacked nanosheet structures, the first type epitaxial layer 130 for both the bottom nanosheet structures NS1 and the top nanosheet structures NS2 are shown to be formed not contacting each other. This would allow for a two separate metal MOL contacts to be connected to both epitaxial layers 130. However, it should be appreciated that in other embodiments, the growth of the epitaxial layers 130 may be continued to the point that the top and bottom portions are merged (i.e., directly contacting each other), as shown in FIG. 21. This may allow for a single metal contact to connect to both epitaxial layers 130. It should also be appreciated that the merging of the top/bottom epitaxial layers may apply to any of a P/P type epitaxial configuration, an N/N type epitaxial configuration, a P/N type epitaxial configuration or a N/P type epitaxial configuration. It should also be appreciated that in a given semiconductor device 100, a first set of stacked nanosheet structures may include merged epitaxial layers, and a second set of stacked nanosheet structures may include non-merged epitaxial layers. Also, where there is a merger of the source/drain epitaxial layers of the top and bottom nanosheet structures for either the P/P type or the N/N type, this may allow for a high current device. This may be considered to be the equivalent of a FET device which comprises the sum of the channels of the top and the bottom FET (i.e., multiple channels of stacked FETs of the same polarity). Also, as mentioned above, in the case of either merged P/P or N/N, the merged FETs only need one MOL contact for the terminals of the source and the drain. In the case of P/N or N/P, the merged FETs may utilize two contacts, one for the nFET and one for the pFET.

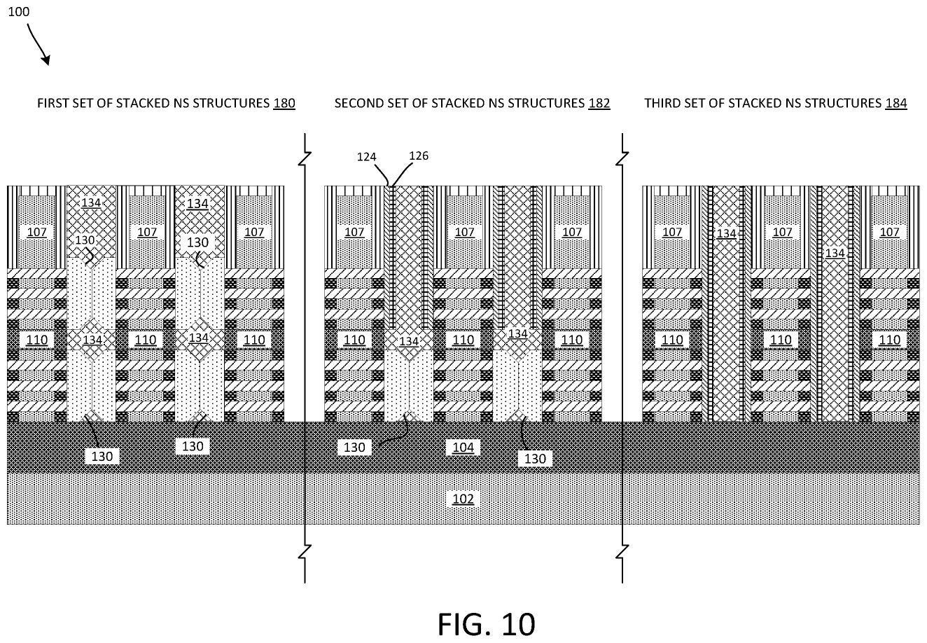

Referring now to FIG. 10, this figure is a cross-sectional view of the semiconductor device 100 of FIG. 9 after additional fabrication operations, according to embodiments. As shown in FIG. 10, a second gap fill layer 134 is formed around the first type epitaxial layer 130. It should be appreciated that the second gap fill layer 134 may be comprised of the same or different material(s) as the first gap fill layer 112. This is generally a deposition of a conformal layer (ALD type) and a gap fill material such as oxide FCVD. In certain examples, this may be only the oxide FCVD. It should be appreciated that in other embodiments, a nitride layer (not shown) may be conformally deposited before forming the second gap fill layer 134. This would add another liner to the blocking sidewall spacer (e.g., the oxide layer 124 and nitride layer 126) of second set of stacked nanosheet structures 182 and the third set of stacked nanosheet structures 184, and this nitride layer would need to be removed later with the blocking sidewall spacer layer removal steps.

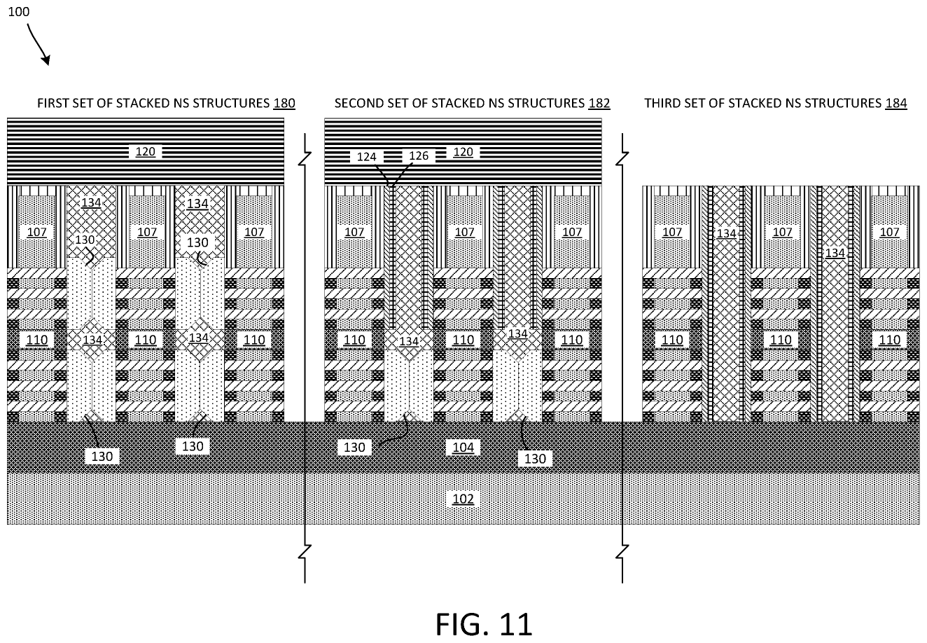

Referring now to FIG. 11, this figure is a cross-sectional view of the semiconductor device 100 of FIG. 10 after additional fabrication operations, according to embodiments. As shown in FIG. 10, another mask 120 is formed on the first set of stacked nanosheet structures 180 and the second set of stacked nanosheet structures 182 according to standard lithographic procedures.

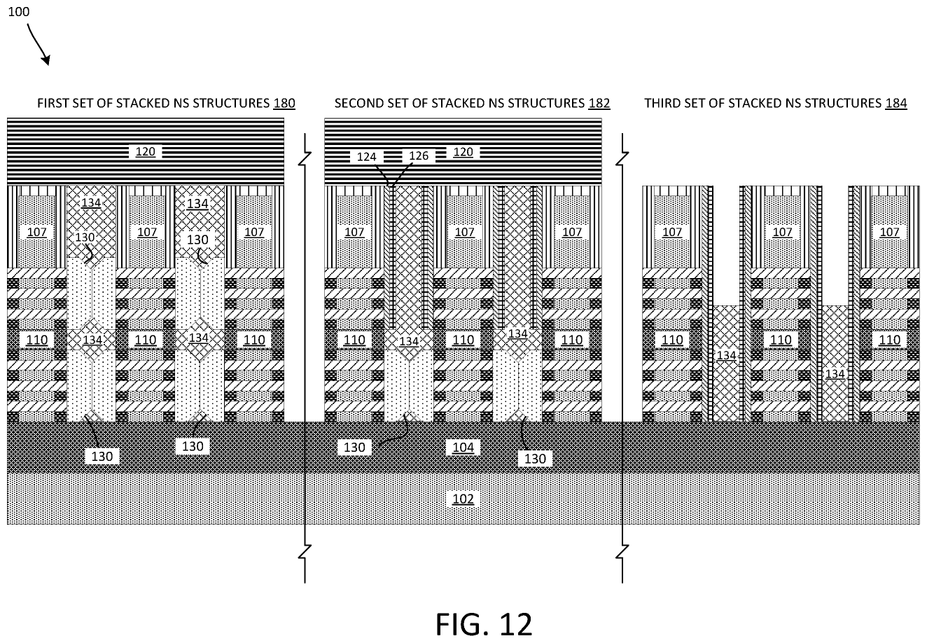

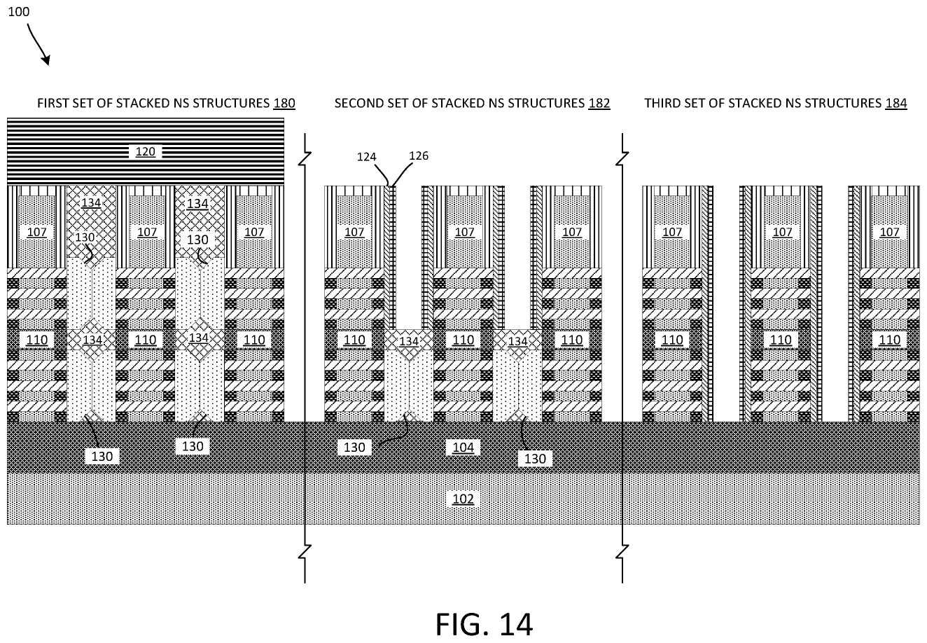

Referring now to FIG. 12, this figure is a cross-sectional view of the semiconductor device 100 of FIG. 11 after additional fabrication operations, according to embodiments. As shown in FIG. 12, after the mask 120 is formed, a suitable material removal process, such as reactive ion etching (RIE), wet etching or COR, is used to remove a portion of the second gap fill layer 134 in the region corresponding to the third set of stacked nanosheet structures 184. In this example, the second gap fill layer 134 in the region corresponding to the third set of stacked nanosheet structures 184 is removed down to a lower level. This thickness is therefore equal to or less than a height of the gap fill layer 134 thickness for the second set of stacked nanosheet structures 182. The material removal step here creates a vertical offset that corresponds approximately to the height of the bottom FET, such that when the stacked FETs for the third set of stacked nanosheet structures 184 will have the top FETs exposed. It should be appreciated that the material of the second gap fill layer 134 in the region corresponding to the third set of stacked nanosheet structures 184 may be removed to a different depth than that shown in FIG. 12 provided that the remainder of the material of the second gap fill layer 134 in this region can be completely removed in a subsequent material removal step (see also, FIG. 14).

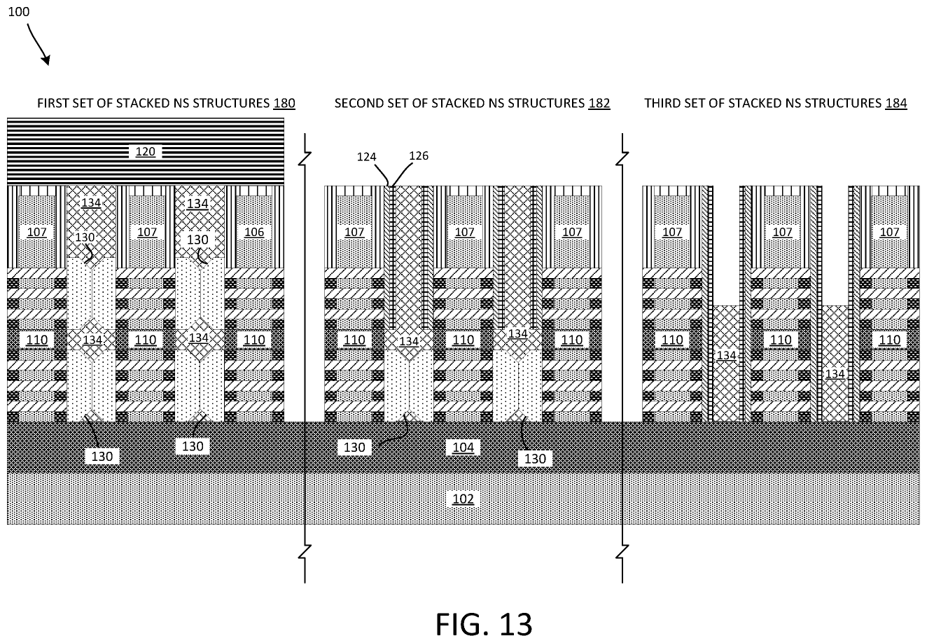

Referring now to FIG. 13, this figure is a cross-sectional view of the semiconductor device 100 of FIG. 12 after additional fabrication operations, according to embodiments. As shown in FIG. 13, the mask 120 is removed and a new mask 120 is formed in the area over the first set of stacked nanosheet structures 180 according to standard lithographic procedures. Thus, at this stage, the hardmask 116 and the second gap fill layer 134 in the area corresponding to the second set of stacked nanosheet structures 182 and the third set of stacked nanosheet structures 184 are exposed for further processing.

Referring now to FIG. 14, this figure is a cross-sectional view of the semiconductor device 100 of FIG. 13 after additional fabrication operations, according to embodiments. As shown in FIG. 14, a suitable material removal process is employed to remove additional material of the second gap fill layer 134. In particular, all of the material of the second gap fill layer 134 is removed in the area corresponding to the third set of stacked nanosheet structures 184. However, in the area corresponding to the second set of stacked nanosheet structures 182, an amount of the second gap fill layer 134 is left on top of the first type epitaxial layer 130. In other embodiments where there are merged epitaxial layers, an amount of the gap fill layer 134 is not left on top of the first type epitaxial layer 130 for the second set of stacked epitaxial structures 182.

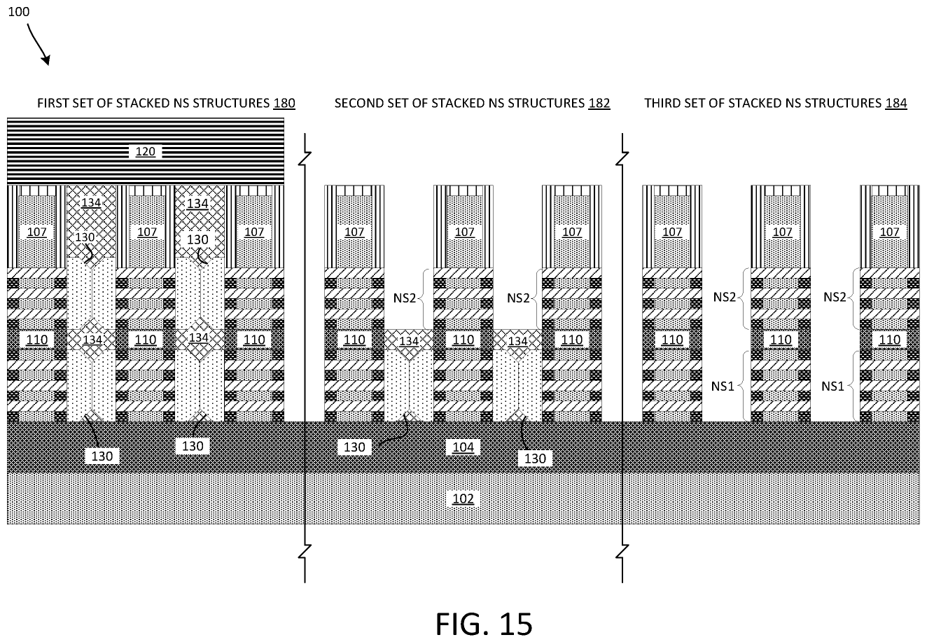

Referring now to FIG. 15, this figure is a cross-sectional view of the semiconductor device 100 of FIG. 14 after additional fabrication operations, according to embodiments. As shown in FIG. 15, the remaining material of the oxide layer 124 and nitride layer 126 (or more generally these two layers are merely one example of a blocking sidewall spacer, which could include different materials or be composed of a different number of layers other than two) are removed. This will allow for subsequent growth of a second type epitaxial layer in these areas, as discussed below.

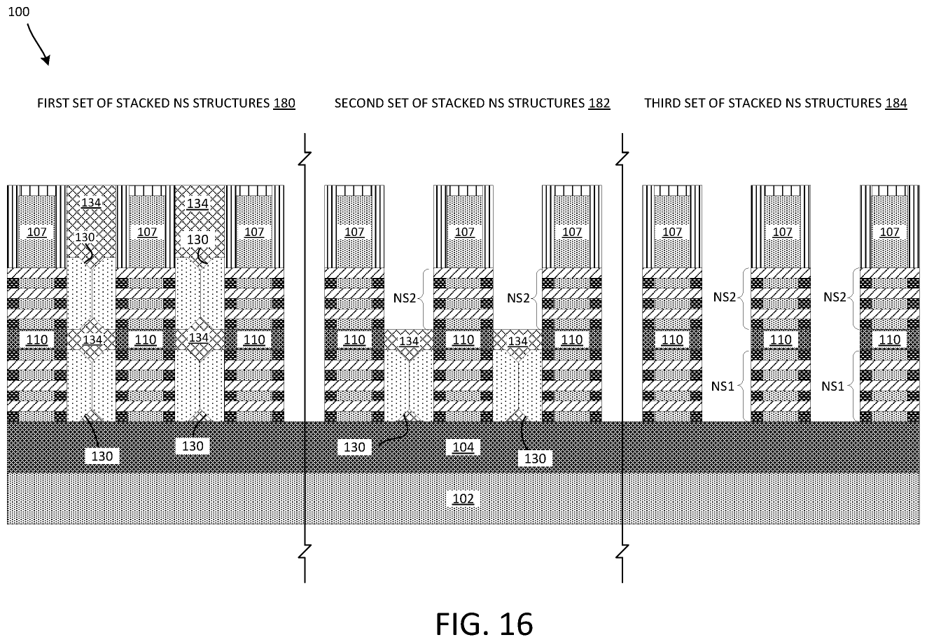

Referring now to FIG. 16, this figure is a cross-sectional view of the semiconductor device of FIG. 15 after additional fabrication operations, according to embodiments. As shown in FIG. 16, a suitable material removal process is used to remove the mask 120 from the area corresponding to the first set of stacked nanosheet structures 180.

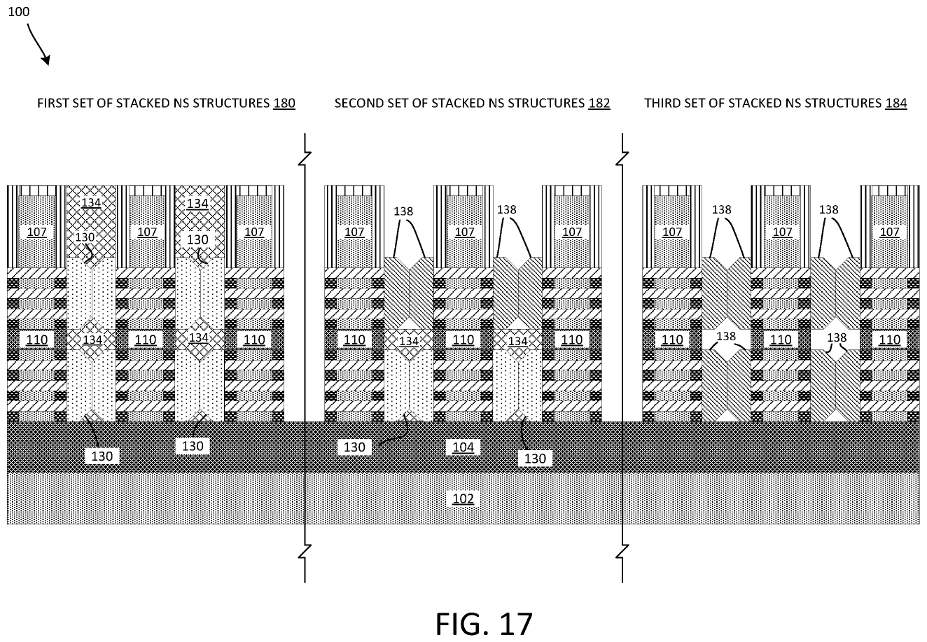

Referring now to FIG. 17, this figure is a cross-sectional view of the semiconductor device of FIG. 16 after additional fabrication operations, according to embodiments. As shown in FIG. 17, second type epitaxial layers 138 are formed on the exposed top nanosheet structures NS2 of the second set of stacked nanosheet structures 182. The second type epitaxial layers 138 are also formed on the top nanosheet structures NS2 and the bottom nanosheet structures NS1 in the third set of stacked nanosheet structures 184. In one example the first type epitaxial layers 130 and the second type epitaxial layers include a SiGe based material. It should also be appreciated that in some examples, the first type epitaxial layers 130 comprise a p-type material and the second type epitaxial layers 138 comprise an n-type material. In other examples, the order may be the opposite, where the first type epitaxial layers 130 comprise an n-type material and the second type epitaxial layers 138 comprise a p-type material.

In general, in determining the difference between p-type and n-type semiconductors, factors such as the doping elements, the effect of the doping elements, the majority and minority carriers in both types are taken into consideration. Additionally, the density of electrons and holes, energy levels and Fermi level, the direction of movement of majority carriers, are also accounted for in clarifying the disparity between p-type and n-type semiconductors. Thus, as a main difference, in n-type semiconductors, the electrons have a negative charge, hence the name n-type. While in p-type semiconductors, the effect of a positive charge is generated in the absence of an electron, hence the name p-type. In certain examples, in a p-type semiconductor, the III group element of the periodic table is added as a doping element, while in n-type the doping element is the V group element. In a p-type semiconductor, the majority carriers are holes, and the minority carriers are electrons, whereas in the n-type semiconductor, electrons are the majority carriers, and holes the minority carriers.

Although in the embodiment shown in FIG. 17, the epitaxial layers (i.e., either first type epitaxial layers 130 or second type epitaxial layers 138) are shown to not contact each other at the level of the MDI layers 110 due to the presence of the second gap fill layer 134 in between, in other embodiments the growth of the epitaxial layers on the bottom nanosheet structure NS1 and the top nanosheet material-containing stacks may be continued such that the epitaxial layers directly contact each other. That is, in the first set of stacked nanosheet structures 180 the bottom and top first type epitaxial layers 130 would contact each other, in the second set of stacked nanosheet structures 182 the top second type epitaxial layer 138 would contact the bottom first type epitaxial layer 130, and in the third set of stacked nanosheet structures 184 the bottom and top second type epitaxial layers 138 would contact each other.

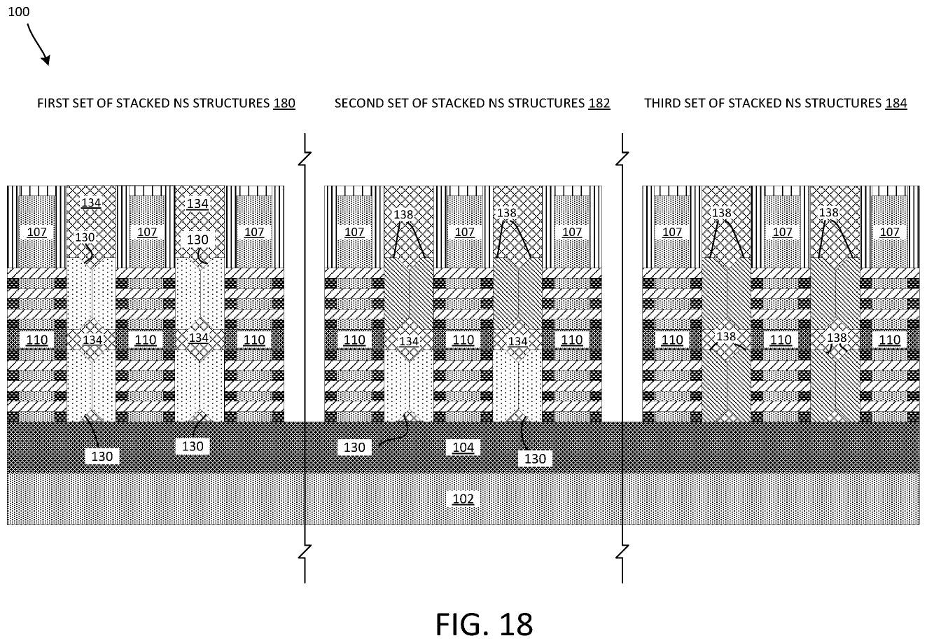

Referring now to FIG. 18, this figure is a cross-sectional view of the semiconductor device of FIG. 17 after additional fabrication operations, according to embodiments. As shown in FIG. 18, additional material of the second gap fill layer 134 is deposited to fill in the remaining open areas around the first type epitaxial layers 130 and the second type epitaxial layers 138, and between the various nanosheet stacks.

In certain embodiments, although not shown in FIGS. 1-18 (see however, FIGS. 19 and 20 for an example showing this feature), a gate cut patterning process is performed to etch away the dummy gate 107 in a gate cut region, followed by filling the gate cut region with dielectric material. Then, the dummy gate is selectively removed, followed by removal of (or release of) the SiGe material of the sacrificial layers. After the material of the sacrificial layers has been released, a high-K metal gate (HKMG) dielectric layer (not shown) and a gate electrode (i.e., that includes a work function metal (WFM)) are formed in the spaces created by the removal of the SiGe material of the sacrificial layers. In certain examples, the forming of the gate structure includes forming a continuous layer of gate dielectric material and a gate electrode material inside the gate opening. The continuous layer of gate dielectric material can include silicon oxide, or a dielectric material having a dielectric constant greater than 4.0 (such dielectric materials can be referred to as a high-K metal gate dielectric material). Illustrative examples of high-k gate dielectric materials include metal oxides such as, for example, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The HKMG dielectric layer dielectric material can further include dopants such as lanthanum (La), aluminum (Al) and/or magnesium (Mg). The continuous layer of the high-k metal gate can be formed utilizing a deposition process such as, for example, ALD, CVD, PECVD, or PVD. The continuous layer of the HKMG dielectric layer is a conformal layer having a thickness which can range from 1 nm to 10 nm.

After this, an n-type or p-type work function metal (WFM) layer (not shown in FIG. 18) is deposited in the spaces created by the previous removal of the sacrificial layers 106 in the bottom nanosheet structure NS1 to form the gate electrode structure. Similarly, an n-type or p-type WFM layer is deposited in the spaces created by the previous removal of the sacrificial layers 106 in the top nanosheet structure NS2. The different WFM layers form the gate electrode structures. The WFM layers can be used to set a threshold voltage of the FET to a desired value. In some embodiments, the layer of WFM can be selected to effectuate an n-type threshold voltage shift. “N-type threshold voltage shift” as used herein means a shift in the effective work-function of the work-function metal-containing material towards a conduction band of silicon in a silicon-containing material. In solid-state physics, the work function is the minimum thermodynamic work (i.e., energy) needed to remove an electron from a solid to a point in the vacuum immediately outside the solid surface. Also, this energy (work function) is a measure of how firmly a particular metal holds its electrons. In general, the conduction band is the range of permissible energy values which an electron in a solid material can have that allows the electron to dissociate from a particular atom and become a free charge carrier in the material. In one embodiment, the work function of the n-type work function metal ranges from approximately 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations and thereof. In other embodiments, the layer of WFM can be selected to effectuate a p-type threshold voltage shift. In one embodiment, the work function of the p-type work function metal ranges from approximately 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. In general, the valence band is the range of permissible energy values that are the highest energies an electron can have and still be associated with a particular atom of a solid material. Examples of such materials that can effectuate a p-type threshold voltage shift include, but are not limited to, titanium nitride, and tantalum carbide, hafnium carbide, and combinations thereof. The layers of WFM are conformal layers which can be formed by a conformal deposition process such as, for example, ALD, CVD or PECVD. The layer of WFM layer can have a thickness in the range of approximately 1 nm to 20 nm, although other thicknesses above or below this range may be used as desired for a particular application. In the embodiment shown in FIGS. 1-18, the NFET or PFET work function metal (WFM) layers are deposited in the spaces created by the previous removal of the sacrificial layers 106 in the bottom nanosheet structure NS1, and the NFET or PFET WFM layer is deposited in the spaces created by the previous removal of the sacrificial layers 106 in the top nanosheet structure NS2.

It should be appreciated that in certain embodiments, the bottom nanosheet structure NS1 may include a PFET (or p-type) WFM layer and a p-type epitaxial layer, and the top nanosheet structure NS2 may include an NFET (or n-type) WFM layer and an n-type epitaxial layer. This combination of layers with these materials results in a first type of device having a first type of functionality (e.g., a stacked CMOS device).

In certain embodiments, the bottom nanosheet structure NS1 may include an NFET (or n-type) WFM layer and an n-type epitaxial layer, and the top nanosheet structure NS2 may include a PFET (or n-type) WFM layer and a p-type epitaxial layer. This combination of layers with these materials results in the first type of device having the first type of functionality (e.g., a stacked CMOS device), where the order to the p-type and n-types is reversed compared with the previous example.

In certain embodiments, both the bottom nanosheet structure NS1 and the top nanosheet structure NS2 include an NFET (or n-type) WFM layer and an n-type epitaxial layer. This combination of layers with these n-type materials results in another type of device having a different type of functionality (e.g., a stacked nFET for a high drive current device).

In certain embodiments, both the bottom nanosheet structure NS1 and the top nanosheet structure NS2 include a PFET (or p-type) WFM layer and a p-type epitaxial layer. This combination of layers with these p-type materials results in another type of device having a different type of functionality (e.g., a stacked pFET for a high drive current device).

Referring now to FIG. 19, this figure is a cross-sectional view of a semiconductor device 200 including a single pFET standard drive current device 260 and a single nFET standard drive current device 262, according to embodiments. As discussed above with regard to the embodiments shown in FIGS. 1-18, after the formation of the epitaxial layers, further processing is performed to remove the sacrificial layers and replace them with some combination of NFET WFM layers and PFET WFM layers. FIG. 19 shows one example of a semiconductor device 200 after the sacrificial layers have been removed and the WFM layers have been added. A bottom dielectric isolation layer 204 is formed on the substrate 202.

As shown in FIG. 19, for the single pFET standard drive current device 260, the bottom nanosheet structure NS1 includes a p-type WFM layer 208, but does not include a p-type epitaxial layer, and the top nanosheet structure NS2 includes a p-type WFM layer and an p-type epitaxial layer 230. This combination of layers with these p-type materials results in another type of device having a different type of functionality (e.g., a single pFET for a standard drive current device, which is distinguishable from the stacked pFET for a high drive current device described above that has epitaxial layers on both the top and bottom). It should be appreciated that the single p-type epitaxial layer 230 may be either on the top nanosheet structure NS2 or the bottom nanosheet structure NS1. The single pFET standard drive current device 260 includes bottom NS stacks NS1 including alternating layers of an p-type WFM layer 250 and a semiconductor layer 208. However, unlike the embodiments discussed above with respect to FIGS. 1-18, the single pFET standard drive current device 260 does not include epitaxial layers on the bottom nanosheet structure NS1. Similar to the embodiments discussed above, inner spacers 214 and MDI layer 210 are also formed. The single pFET standard drive current device 260 also includes a top nanosheet structure NS2 including alternating layers of a p-type WFM layer 250 and a semiconductor layer 208 (which may also be referred to as a gate electrode that wraps around the channels). The bottom nanosheet structure NS1 also includes the p-type WFM layer 250 even though it does not include the epitaxial layers. The single pFET standard drive current device 260 of the semiconductor device 200 also includes gate material layer 207, gate spacers 215. The material of the gate material layer 207 may include the same material(s) or different material(s) as the p-type WFM layer 250. Thus, in the embodiment shown in FIG. 19 it can be seen that this FET device is a not a stacked FET device as shown in FIGS. 1-18 because the epitaxial layer is not formed on the bottom NS stacks NS1.

As shown in FIG. 19, for the single nFET standard drive current device 262, the bottom nanosheet structure NS1 includes an n-type WFM layer 206 and an n-type epitaxial layer 238, and the top nanosheet structure NS2 includes an n-type WFM layer 206 but does not include an n-type epitaxial layer. This combination of layers with these n-type materials results in another type of device having a different type of functionality (e.g., a single nFET for a standard drive current device, which is distinguishable from the stacked nFET for a high drive current device described above that has epitaxial layers on both the top and bottom). It should be appreciated that the single n-type epitaxial layer 230 may be either on the top nanosheet structure NS2 or the bottom nanosheet structure NS1, and the device will function the same way regardless of the position. As also shown in FIG. 19, the single nFET standard drive current device 262 also includes bottom NS stacks NS1 including alternating layers of an n-type WFM layer 206 and a semiconductor layer 208, and the n-type epitaxial layer 238 is formed between these bottom NS stacks NS1. The single nFET standard drive current device 262 also includes top NS stacks NS2 including alternating layers of an n-type WFM layer 206 and a semiconductor layer 208. However, unlike the embodiments discussed above with respect to FIGS. 1-18, the single nFET standard drive current device 262 does not include epitaxial layers on the top NS stacks NS2. Similar to the embodiments discussed above, inner spacers 214 and MDI layer 210 are also formed. The single nFET standard drive current device 262 of the semiconductor device 200 also includes gate material layer 209, gate spacers 215. The material of the gate material layer 209 may include the same material(s) or different material(s) as the n-type WFM layer 206. Thus, in the embodiment shown in FIG. 19 it can be seen that this FET device is a not a stacked FET device as shown in FIGS. 1-18 because the n-type epitaxial layer 238 is not formed on the top NS stacks NS2.

Also shown in FIG. 19 is an gap fill layer 234 that is formed around the p-type epitaxial layers 230 and the n-type epitaxial layers 238, as well as between the nanosheet stacks. It should be appreciated that the p-type epitaxial layer 230 may be formed between the bottom NS stacks NS1 rather than the top NS stacks NS2, as shown in FIG. 19. It should also be appreciated that the n-type epitaxial layer 238 may be formed on the top NS stacks NS2 rather than the bottom NS stacks NS1, as shown in FIG. 19. It should also be appreciated that both the p-type epitaxial layers 230 and the n-type epitaxial layers 238 may be formed on either the bottom NS stacks NS1 or the top NS stacks NS2. Varying the position (i.e., top versus bottom) of the p-type or n-type may allow for flexibility with regard to manufacturing operations/flow.

FIG. 20 is a cross-sectional view of a semiconductor device 300 including a stacked CMOS device 360, a stacked pFET 362 for high drive current devices and a stacked nFET 364 for high drive current devices, according to embodiments. As discussed above with regard to the embodiments shown in FIGS. 1-18, further processing is performed to remove the sacrificial layers and replace them with some combination of NFET WFM layers and PFET WFM layers. FIG. 20 shows one example of a semiconductor device 300 after the sacrificial layers have been removed and the WFM layers have been added. A bottom dielectric isolation layer 304 is formed on the substrate 302. It should be appreciated that in certain embodiments, the bottom dielectric layer 304 may be omitted. A first nanosheet stack structure is a stacked CMOS device 360, a second nanosheet stack structure is stacked pFET 362 for high drive current devices, and a third nanosheet stack structure is configured as a stacked nFET 364 for high drive current devices.

The stacked CMOS 360 device includes bottom NS stacks NS1 including alternating layers (as seen in this cross-sectional view) of an n-type WFM layer 306 and a semiconductor layer 308, and an n-type epitaxial layer 330 is formed between these bottom NS stacks NS1. The stacked CMOS 360 also includes top NS stacks NS2 including alternating layers of a p-type WFM layer 350 and a semiconductor layer 308, and a p-type epitaxial layer 338 is formed between these top NS stacks NS2. Similar to the embodiments discussed above, inner spacers 314 and MDI layer 310 are also formed. The stacked CMOS 360 device of the semiconductor device 300 also includes a gate material layer 307, gate spacers 315. The material of the gate material layer 307 may include the same material(s) or different material(s) as the p-type WFM layer 350.

The stacked pFET 362 for high drive current devices includes bottom NS stacks NS1 including alternating layers of a p-type WFM layer 350 and a semiconductor layer 308, and a p-type epitaxial layer 338 is formed between these bottom NS stacks NS1. The stacked pFET 362 also includes top NS stacks NS2 including alternating layers of a p-type WFM layer 350 and a semiconductor layer 308, and a p-type epitaxial layer 338 is formed between these top NS stacks NS2. Similar to the embodiments discussed above, inner spacers 314 and MDI layer 310 are also formed. The stacked pFET 362 device of the semiconductor device 300 also includes a gate material layer 307, gate spacers 315. The material of the gate material layer 307 is a p-type material may include the same material(s) or different material(s) as the p-type WFM layer 350. Thus, for the stacked pFET, p-type nanosheet stacks and epitaxial layers are formed on both the top and bottom nanosheet stacks NS1 and NS2. Accordingly, a second type of device (i.e., different from the stacked CMOS 360) may be formed in the same overall semiconductor device 300. In other words, the stacked pFET 362 functions as a second type of device that is functionally and structurally different from the stacked CMOS device 360 because it includes two stacked p-type epitaxial layers 338 and two corresponding p-type WFM layers 350 rather than including a p-type epitaxial layer 338 on the top and an n-type epitaxial layer 330 on the bottom (or vice versa). Thus, a semiconductor device 300 can be achieved with a combination of two different types of devices (i.e., stacked CMOS and stacked pFET).

The stacked nFET 364 for high drive current devices includes bottom NS stacks NS1 including alternating layers of a n-type WFM layer 306 and a semiconductor layer 308, and an n-type epitaxial layer 330 is formed between these bottom NS stacks NS1. The stacked nFET 364 also includes top NS stacks NS2 including alternating layers of an n-type WFM layer 306 and a semiconductor layer 308, and an n-type epitaxial layer 330 is formed between these top NS stacks NS2. Similar to the embodiments discussed above, inner spacers 314 and MDI layer 310 are also formed. The stacked nFET 364 device of the semiconductor device 300 also includes a gate material layer 309, and gate spacers 315. The material of the gate material layer 309 is an n-type material and may include the same material(s) or different material(s) as the n-type WFM layer 306. Thus, for the stacked nFET 364, n-type nanosheet stacks and epitaxial layers are formed on both the top and bottom nanosheet stacks NS1 and NS2. Accordingly, a third type of device (i.e., different from the stacked CMOS 360 and the stacked pFET 362) may be formed in the same overall semiconductor device 300. In other words, the stacked nFET 364 functions as a third type of device that is functionally and structurally different from both the stacked CMOS device 360 and the stacked pFET 362 because it includes two stacked n-type epitaxial layers 330 and two corresponding n-type WFM layers 306, which is different from the stacked CMOS device 360 and the stacked pFET 362. Thus, a semiconductor device 300 can be achieved with a combination of three different types of devices (i.e., stacked CMOS and stacked pFET) that are formed at the same level.

As in the other embodiments, it should be appreciated that, in other examples, the semiconductor device 300 may be altered to change the positions of the n-type and p-type components. It should also be appreciated that the formation of the different n-type and p-type epitaxial layers and WFM metal layers shown in FIG. 20 could apply to the embodiments shown in FIGS. 1-18. It should also be appreciated that the semiconductor device 300 may include a combination of only two different types of devices rather than three. It should further be appreciated that the semiconductor device 300 may include a combination of one or more of the devices shown in FIG. 20 (i.e., stacked CMOS device 360, stacked pFET 362 and stacked nFET) and one or more of the devices shown in FIG. 19 (i.e., single pFET 260 and single nFET 262).

Some embodiments of the present disclosure can take the form of a first semiconductor device. The first semiconductor device includes a first stacked nanosheet structure and a second stacked nanosheet structure each including a first nanosheet structure formed at a first level and a second nanosheet structure formed at a second level. A configuration of the first stacked nanosheet structure on the first level is different than a configuration of the second stacked nanosheet structure on the first level, or the configuration of the first stacked nanosheet structure on the second level is different than a configuration of the second stacked nanosheet structure on the second level. According to the present embodiments, different stacked nanosheet structures having different configurations for the second and first nanosheet structure can be combined in a single semiconductor device. This may allow for simplification of the overall manufacturing process by enabling formation of different types of devices at the same manufacturing level. This may also allow increased flexibility with regard to having a semiconductor device with two or more different types of stacked nanosheet structures.

In some embodiments of the first semiconductor device, for the first and second stacked nanosheet structures, at least one of the respective second nanosheet structures and the first nanosheet structure is a field effect transistor (FET) that includes a nanosheet stack in contact with an epitaxial layer. This may allow for increased flexibility with regard to having multiple FET stacked nanosheet stacks with different configurations.

In some embodiments of the first semiconductor device, the first nanosheet structure of the first stacked nanosheet structure includes a p-type epitaxial layer, and the first nanosheet structure of the second stacked nanosheet structure includes an n-type epitaxial layer. The first nanosheet structure of the first stacked nanosheet structure includes alternating layers of a semiconductor layer and a p-type work function metal (WFM) layer. Also, the first nanosheet structure of the second stacked nanosheet structure includes alternating layers of the semiconductor layer and an n-type work function metal (WFM) layer. This may allow for increased flexibility with regard to having multiple stacked nanosheet stacks with different n-type and p-type configurations for the WFM layers and the epitaxial layers.

In some embodiments of the first semiconductor device, the second nanosheet structure of the first stacked nanosheet structure includes a p-type epitaxial layer, and the first nanosheet structure of the second stacked nanosheet structure includes an n-type epitaxial layer. This may allow for increased flexibility with regard to having multiple stacked nanosheet stacks with different n-type and p-type configurations, which may result in design flexibility.

In some embodiments of the first semiconductor device, the second nanosheet structure of the first stacked nanosheet structure includes an n-type epitaxial layer, and the first nanosheet structure of the first stacked nanosheet structure includes a p-type epitaxial layer. The second nanosheet structure of the second stacked nanosheet structure includes an n-type epitaxial layer, and the first nanosheet structure of the second stacked nanosheet structure includes an n-type epitaxial layer. This may allow for increased flexibility with regard to having multiple stacked nanosheet stacks with different n-type and p-type configurations, which may result in design flexibility.

In some embodiments of the first semiconductor device, the n-type epitaxial layer and the p-type epitaxial layer of the first stacked nanosheet structure are in direct contact with each other. Also, the n-type epitaxial layer and the n-type epitaxial layer of the second stacked nanosheet structure are in direct contact with each other. These embodiments may allow for a single metal contact to connect the BEOL/MOL resources to the merged epitaxial layers, rather than two separate contacts if they are separated. This may allow for design flexibility.

In some embodiments of the first semiconductor device, the n-type epitaxial layer and the p-type epitaxial layer of the first stacked nanosheet structure are separated by a gap fill layer. Also, the n-type epitaxial layer and the n-type epitaxial layer of the second stacked nanosheet structure are separated by the MDI layer. These embodiments may allow for two metal contacts to connect the BEOL/MOL resources to the non-merged epitaxial layers.

In some embodiments of the first semiconductor device, a third stacked nanosheet structure includes a first nanosheet structure and a second nanosheet structure. A configuration of the respective nanosheet structures for the third stacked nanosheet structure is different than the configurations of the respective nanosheet structures for the second stacked nanosheet structure and the third stacked nanosheet structure. This may allow for increased flexibility with regard to having at least six types (i.e., P/P, N/N, P/N, N/P, /P, /N) of stacked nanosheet stacks with different configurations for the same semiconductor device, which may result in design flexibility.

In some embodiments of the first semiconductor device, the first stacked nanosheet structure is a stacked complementary metal oxide semiconductor (CMOS) device where the first nanosheet structure includes an n-type epitaxial layer and the second nanosheet structure includes a p-type epitaxial layer. This may allow for increased flexibility with regard to having multiple stacked nanosheet structures with different configurations where one of the stacked nanosheet structures is configured as a stacked CMOS device. Forming these differently configured stacked nanosheet structures at the same level may also result in design flexibility.

In some embodiments of the first semiconductor device, the second stacked nanosheet structure is a stacked p-type field effect transistor (pFET) device where the first nanosheet structure includes a p-type epitaxial layer and the second nanosheet structure includes a p-type epitaxial layer. This may allow for having multiple stacked nanosheet structures with different configurations where one of the stacked nanosheet structures is configured as a stacked pFET device. Forming these differently configured stacked nanosheet structures at the same level may also result in design flexibility.

In some embodiments of the first semiconductor device, the third stacked nanosheet structure is a stacked n-type field effect transistor (nFET) device where the first nanosheet structure includes an n-type epitaxial layer and the second nanosheet structure includes an n-type epitaxial layer. This may allow for increased flexibility with regard to having multiple stacked nanosheet structures with different configurations where one of the stacked nanosheet structures is configured as a stacked nFET device. Forming these differently configured stacked nanosheet structures at the same level may also result in design flexibility.

In some embodiments of the first semiconductor device, the first nanosheet structure for the first stacked nanosheet structure is formed at a same level as the first nanosheet structure for the second stacked nanosheet structure. Also, the second nanosheet structure for the second stacked nanosheet structure is formed at a same level with the second nanosheet structure for the second stacked nanosheet structure. This may allow for increased flexibility with regard to having multiple stacked nanosheet structures with different configurations. Forming these differently configured stacked nanosheet structures at the same level may also result in design flexibility.

In some embodiments of the first semiconductor device, the first nanosheet structure of the first stacked nanosheet structure includes a p-type epitaxial layer and the second nanosheet structure of the first stacked nanosheet structure includes an n-type epitaxial layer. The first nanosheet structure of the second stacked nanosheet structure includes an n-type epitaxial layer and the second nanosheet structure of the second stacked nanosheet structure includes an n-type epitaxial layer. This may allow for increased flexibility with regard to having multiple stacked nanosheet structures with different n-type and p-type configurations. Forming these differently configured stacked nanosheet structures at the same level may also result in design flexibility.

In some embodiments of the first semiconductor device, the first nanosheet structure of the first stacked nanosheet structure includes a p-type epitaxial layer and the second nanosheet structure of the first stacked nanosheet structure includes an n-type epitaxial layer. Also, the first nanosheet structure of the second stacked nanosheet structure includes a p-type epitaxial layer and the second nanosheet structure of the second stacked nanosheet structure includes another p-type epitaxial layer. This may allow for increased flexibility with regard to having multiple stacked nanosheet structures with different n-type and p-type configurations. Forming these differently configured stacked nanosheet structures at the same level may also result in design flexibility.

In some embodiments of the first semiconductor device, the first nanosheet structure of the first stacked nanosheet structure includes an n-type epitaxial layer and the second nanosheet structure of the first stacked nanosheet structure includes a p-type epitaxial layer. The first nanosheet structure of the second stacked nanosheet structure includes a p-type epitaxial layer and the second nanosheet structure of the second stacked nanosheet structure includes another p-type epitaxial layer. This may allow for increased flexibility with regard to having multiple stacked nanosheet structures with different n-type and p-type configurations. Forming these differently configured stacked nanosheet structures at the same level may also result in design flexibility.

Some embodiments of the present disclosure can take the form of an electronic device including a semiconductor device. The semiconductor device includes a first stacked nanosheet structure and a second stacked nanosheet structure each including a first nanosheet structure formed at a first level and a second nanosheet structure formed at a second level. A configuration of the first stacked nanosheet structure on the first level is different than a configuration of the second stacked nanosheet structure on the first level, or the configuration of the first stacked nanosheet structure on the second level is different than a configuration of the second stacked nanosheet structure on the second level. According to the present embodiments, different stacked nanosheet structures having different configurations for the second and first nanosheet structure can be combined in a single semiconductor device. This may allow for simplification of the overall manufacturing process by enabling formation of different types of devices at the same manufacturing level. This may also allow increased flexibility with regard to having a semiconductor device with two or more different types of stacked nanosheet structures.

In some embodiments of the electronic device, for the first and second stacked nanosheet structures, at least one of the respective second nanosheet structures and the first nanosheet structure is a field effect transistor (FET) that includes a nanosheet stack in contact with an epitaxial layer. This may allow for increased flexibility with regard to having multiple FET stacked nanosheet stacks with different configurations.

In some embodiments of the electronic device, the first nanosheet structure of the first stacked nanosheet structure includes a p-type epitaxial layer, and the first nanosheet structure of the second stacked nanosheet structure includes an n-type epitaxial layer. The first nanosheet structure of the first stacked nanosheet structure includes alternating layers of a semiconductor layer and a p-type work function metal (WFM) layer. Also, the first nanosheet structure of the second stacked nanosheet structure includes alternating layers of the semiconductor layer and an n-type work function metal (WFM) layer. This may allow for increased flexibility with regard to having multiple stacked nanosheet stacks with different n-type and p-type configurations for the WFM layers and the epitaxial layers.

In some embodiments of the electronic device, the second nanosheet structure of the first stacked nanosheet structure includes a p-type epitaxial layer, and the first nanosheet structure of the second stacked nanosheet structure includes an n-type epitaxial layer. This may allow for increased flexibility with regard to having multiple stacked nanosheet stacks with different n-type and p-type configurations, which may result in design flexibility.

In some embodiments of the electronic device, the second nanosheet structure of the first stacked nanosheet structure includes an n-type epitaxial layer, and the first nanosheet structure of the first stacked nanosheet structure includes a p-type epitaxial layer. The second nanosheet structure of the second stacked nanosheet structure includes an n-type epitaxial layer, and the first nanosheet structure of the second stacked nanosheet structure includes an n-type epitaxial layer. This may allow for increased flexibility with regard to having multiple stacked nanosheet stacks with different n-type and p-type configurations, which may result in design flexibility.

In some embodiments of the electronic device, the n-type epitaxial layer and the p-type epitaxial layer of the first stacked nanosheet structure are in direct contact with each other. Also, the n-type epitaxial layer and the n-type epitaxial layer of the second stacked nanosheet structure are in direct contact with each other. These embodiments may allow for a single metal contact to connect the BEOL/MOL resources to the merged epitaxial layers, rather than two separate contacts if they are separated. This may allow for design flexibility.

In some embodiments of the electronic device, the n-type epitaxial layer and the p-type epitaxial layer of the first stacked nanosheet structure are separated by a gap fill layer. Also, the n-type epitaxial layer and the n-type epitaxial layer of the second stacked nanosheet structure are separated by the MDI layer. These embodiments may allow for two metal contacts to connect the BEOL/MOL resources to the non-merged epitaxial layers.

Some embodiments of the present disclosure can take the form of a second semiconductor device. The second semiconductor device includes a first stacked nanosheet structure and a second stacked nanosheet structure each including a first nanosheet structure formed at a first level and a second nanosheet structure formed at a second level, the first and second stacked nanosheet structures including at least one epitaxial layer. A configuration of the at least one epitaxial layer of the first stacked nanosheet structure at the first level is different from a configuration of the at least one epitaxial layer of the second stacked nanosheet structure at the first level, or the configuration of the at least one epitaxial layer of the first stacked nanosheet structure at the second level is different from a configuration of the at least one epitaxial layer of the second stacked nanosheet structure at the second level. This may allow for simplification of the overall manufacturing process by enabling formation of different types of stacked nanosheet structures at the same manufacturing level. This may also allow for increased use applications by having a semiconductor device with two or more different epitaxial configurations for the different stacked nanosheet structures.

In some embodiments of the second semiconductor device, the second nanosheet structure of the first stacked nanosheet structure includes a p-type epitaxial layer, and wherein the first nanosheet structure of the second stacked nanosheet structure includes an n-type epitaxial layer. This enables a semiconductor device including multiple stacked nanosheet structures with different epitaxial configurations, where one structure includes a p-type epitaxial layer and another structure includes an n-type epitaxial layer.

In some embodiments of the second semiconductor device, the first stacked nanosheet structure is a single pFET standard drive current device that includes a gap fill layer covering the first nanosheet structure. This enables a semiconductor device including multiple stacked nanosheet structures with different configurations, where at least one stacked nanosheet structures may be used for applications that utilize a single pFET for standard drive current devices. The gap fill layer covering the first nanosheet structure prevents an epitaxial layer from being formed thereon, thereby resulting in a single FET device rather than a stacked FET device.

In some embodiments of the second semiconductor device, the second stacked nanosheet structure is a single nFET standard drive current device that includes the gap fill layer covering the second nanosheet structure. This enables a semiconductor device including multiple stacked nanosheet structures with different configurations, where at least one stacked nanosheet structure may be used for applications that utilize nFET for standard drive current devices. The gap fill layer covering the second nanosheet structure prevents an epitaxial layer from being formed thereon, thereby resulting in a single FET device rather than a stacked FET device.

In certain embodiments, the semiconductor device contacts the source/drain (S/D) (and/or the gate) from the first side of the device. In certain embodiments, the semiconductor device contacts the source/drain (S/D) (and/or the gate) from the top side of the device.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first stacked nanosheet structure and a second stacked nanosheet structure each including a first nanosheet structure formed at a first level and a second nanosheet structure formed at a second level,
wherein a configuration of the first stacked nanosheet structure on the first level is different than a configuration of the second stacked nanosheet structure on the first level.

2. The semiconductor device of claim 1, wherein for the first and second stacked nanosheet structures, at least one of the respective first nanosheet structures and the second nanosheet structures is a field effect transistor (FET) that includes a nanosheet stack in contact with an epitaxial layer.

3. The semiconductor device of claim 1,
wherein the first nanosheet structure of the first stacked nanosheet structure includes a p-type epitaxial layer, and the first nanosheet structure of the second stacked nanosheet structure includes an n-type epitaxial layer,
wherein the first nanosheet structure of the first stacked nanosheet structure includes alternating layers of a semiconductor layer and a p-type work function metal (WFM) layer, and
wherein the first nanosheet structure of the second stacked nanosheet structure includes alternating layers of the semiconductor layer and an n-type work function metal (WFM) layer.

4. The semiconductor device of claim 1,
wherein the second nanosheet structure of the first stacked nanosheet structure includes a p-type epitaxial layer or n-type epitaxial layer,
wherein the first nanosheet structure of the first stacked nanosheet structure includes the same p-type epitaxial layer or an n-type epitaxial layer as the second nanosheet structure, and
wherein the epitaxial layer of the second nanosheet structure directly contacts the epitaxial layer of the first nanosheet structure.

5. The semiconductor device of claim 1,
wherein the second nanosheet structure of the first stacked nanosheet structure includes an n-type epitaxial layer, and the first nanosheet structure of the first stacked nanosheet structure includes a p-type epitaxial layer, and
wherein the second nanosheet structure of the second stacked nanosheet structure includes the n-type epitaxial layer, and the first nanosheet structure of the second stacked nanosheet structure includes the n-type epitaxial layer.

6. The semiconductor device of claim 1,
wherein the second nanosheet structure of the first stacked nanosheet structure includes a p-type epitaxial layer or an n-type epitaxial layer,
wherein the first nanosheet structure of the first stacked nanosheet structure includes an opposite type epitaxial layer relative to the epitaxial layer of the second nanosheet structure, and
wherein the epitaxial layer of the second nanosheet structure directly contacts the epitaxial layer of the first nanosheet structure.

7. The semiconductor device of claim 6, wherein the epitaxial layer of the second nanosheet structure and the epitaxial layer of the first nanosheet structure share a single metal contact.

8. The semiconductor device of claim 5,
wherein the n-type epitaxial layer and the p-type epitaxial layer of the first stacked nanosheet structure do not directly contact each other, and
wherein the n-type epitaxial layer and the n-type epitaxial layer of the second stacked nanosheet structure do not directly contract each other.

9. The semiconductor device of claim 1, further comprising:
a third stacked nanosheet structure including the first nanosheet structure and the second nanosheet structure,
wherein a configuration of the respective nanosheet structures for the third stacked nanosheet structure is different than the configurations of the respective nanosheet structures for the second stacked nanosheet structure and the third stacked nanosheet structure.

10. The semiconductor device according to claim 8, wherein the first stacked nanosheet structure is a stacked complimentary metal oxide semiconductor (CMOS) device where the first nanosheet structure includes an n-type epitaxial layer and the second nanosheet structure includes a p-type epitaxial layer.

11. The semiconductor device according to claim 9, wherein the second stacked nanosheet structure is a stacked p-type field effect transistor (pFET) device where the first nanosheet structure includes a p-type epitaxial layer and the second nanosheet structure includes a p-type epitaxial layer.

12. The semiconductor device according to claim 10, wherein the third stacked nanosheet structure is a stacked n-type field effect transistor (nFET) device where the first nanosheet structure includes an n-type epitaxial layer and the second nanosheet structure includes an n-type epitaxial layer.

13. The semiconductor device according to claim 1,
wherein the second nanosheet structure of the first stacked nanosheet structure includes an n-type epitaxial layer or a p-type epitaxial layer, and the first nanosheet structure of the first stacked nanosheet structure includes the same type epitaxial layer as the second nanosheet structure,
wherein the epitaxial layer for the second nanosheet structure is separated from the epitaxial layer for the first nanosheet structure, and
wherein the epitaxial layer for the second and first nanosheet structures have separate metal contacts.

14. The semiconductor device according to claim 1,
wherein the first nanosheet structure of the first stacked nanosheet structure includes a p-type epitaxial layer and the second nanosheet structure of the first stacked nanosheet structure includes an n-type epitaxial layer, and
wherein the first nanosheet structure of the second stacked nanosheet structure includes a p-type epitaxial layer and the second nanosheet structure of the second stacked nanosheet structure includes another p-type epitaxial layer.

15. The semiconductor device according to claim 1,
wherein the first nanosheet structure of the first stacked nanosheet structure includes an n-type epitaxial layer and the second nanosheet structure of the first stacked nanosheet structure includes a p-type epitaxial layer, and
wherein the first nanosheet structure of the second stacked nanosheet structure includes a p-type epitaxial layer and the second nanosheet structure of the second stacked nanosheet structure includes another p-type epitaxial layer.

16. An electronic device comprising:
a semiconductor device including
a first stacked nanosheet structure and a second stacked nanosheet structure each including a first nanosheet structure formed at a first level and a second nanosheet structure formed at a second level,
wherein a configuration of the first stacked nanosheet structure on the first level is different than a configuration of the second stacked nanosheet structure on the first level, or the configuration of the first stacked nanosheet structure on the second level is different than a configuration of the second stacked nanosheet structure on the second level.

17. The electronic device of claim 16, wherein for the first and second stacked nanosheet structures, at least one of the respective second nanosheet structures and the first nanosheet structures is a field effect transistor (FET) that includes a nanosheet stack in contact with an epitaxial layer.

18. The electronic device of claim 16,
wherein the first nanosheet structure of the first stacked nanosheet structure includes a p-type epitaxial layer, and the first nanosheet structure of the second stacked nanosheet structure includes an n-type epitaxial layer,
wherein the first nanosheet structure of the first stacked nanosheet structure includes alternating layers of a semiconductor layer and a p-type work function metal (WFM) layer, and
wherein the first nanosheet structure of the second stacked nanosheet structure includes alternating layers of the semiconductor layer and an n-type work function metal (WFM) layer.

19. The electronic device of claim 16,
wherein the second nanosheet structure of the first stacked nanosheet structure includes a p-type epitaxial layer, and
wherein the first nanosheet structure of the second stacked nanosheet structure includes an n-type epitaxial layer.

20. The electronic device of claim 16,
wherein the second nanosheet structure of the first stacked nanosheet structure includes an n-type epitaxial layer, and the first nanosheet structure of the first stacked nanosheet structure includes a p-type epitaxial layer, and
wherein the second nanosheet structure of the second stacked nanosheet structure includes the n-type epitaxial layer, and the first nanosheet structure of the second stacked nanosheet structure includes the n-type epitaxial layer.

21. The electronic device of claim 20,
wherein the n-type epitaxial layer and the p-type epitaxial layer of the first stacked nanosheet structure are in direct contact with each other, and
wherein the n-type epitaxial layer and the n-type epitaxial layer of the second stacked nanosheet structure are in direct contact with each other.

22. A semiconductor device comprising:
a first stacked nanosheet structure and a second stacked nanosheet structure each including a first nanosheet structure formed at a first level and a second nanosheet structure formed at a second level, the first and second stacked nanosheet structures including at least one epitaxial layer, and
wherein a configuration of the at least one epitaxial layer of the first stacked nanosheet structure at the first level is different from a configuration of the at least one epitaxial layer of the second stacked nanosheet structure at the first level, or the configuration of the at least one epitaxial layer of the first stacked nanosheet structure at the second level is different from a configuration of the at least one epitaxial layer of the second stacked nanosheet structure at the second level.

23. The semiconductor device of claim 22,
wherein the second nanosheet structure of the first stacked nanosheet structure includes a p-type epitaxial layer, and
wherein the first nanosheet structure of the second stacked nanosheet structure includes an n-type epitaxial layer.

24. The semiconductor device of claim 22, wherein the first stacked nanosheet structure is a single pFET standard drive current device that includes a gap fill layer covering the first nanosheet structure.

25. The semiconductor device of claim 24, wherein the second stacked nanosheet structure is a single nFET standard drive current device that includes the gap fill layer covering the first nanosheet structure.
